(19) United States
(12) Patent Application Publication
(10) Pub. No.: US 2024/0429236 A1
(43) Pub. Date: Dec. 26, 2024

(54) VARIABLE VERTICAL-STACK NANOSHEET FOR GATE-ALL-AROUND DEVICES

(71) Applicant: QUALCOMM Incorporated, San Diego, CA (US)

(72) Inventors: Shreesh NARASIMHA, Charlotte, NC (US); Yan SUN, San Diego, CA (US); Peijie FENG, San Diego, CA (US)

(21) Appl. No.: 18/339,715

(22) Filed: Jun. 22, 2023

(51) Int. Cl. H01L 27/092; H01L 21/8238; H01L 29/06; H01L 29/08; H01L 29/423; H01L 29/66; H01L 29/775

(52) U.S. Cl. CPC H01L 27/092; H01L 21/823807; H01L 21/823814; H01L 21/823864; H01L 29/0673; H01L 29/0847; H01L 29/42392; H01L 29/66439; H01L 29/66545; H01L 29/66553; H01L 29/775

(57) ABSTRACT

Disclosed are gate-all-around (GAA) devices formed on a nanosheet wafer that includes multiple nanosheet (NS) structures including first and second NS structures. The first NS structure may include N nanosheets, where N≥2. All N nanosheets may function as channels in the first NS structure. The second NS structure may include one or more nanosheets in which N−M of them function as channels, where 1≤M<N.

### FIELD OF DISCLOSURE

This disclosure relates generally to semiconductor devices, and more specifically, but not exclusively, to variable vertical-stack nanosheet for Gate-All-Around (GAA) devices, e.g., CMOS technology devices, to provide flexible design options, and fabrication techniques thereof.

### BACKGROUND

Integrated circuit (IC) technology has achieved great strides in advancing computing power through miniaturization of active components. Three-dimensional devices such as GAA enables miniaturization through stacking of fixed ribbons, also referred to as nanosheets (NS). GAA devices have fixed NS count. Typically, each standard cell lib has 3 or 4 nanosheets per device. The number of nanosheets per device is typically a fundamental limitation to achieving lowest power for example.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary gate-all-around (GAA) device is disclosed. The GAA device may comprise a substrate. The GAA device may also comprise a first nanosheet (NS) structure formed above a first logic area of the substrate. The first NS structure may comprise a plurality of first nanosheets stacked above the substrate. The plurality of first nanosheets may form first channels. A number of first channels may be N, N≥2. The first NS structure may also comprise a first source on the substrate on a first source side of the first channels. The first source may be electrically coupled with the first channels. The first NS structure may further comprise a first drain on the substrate on a first drain side of the first channels opposite the first source side. The first drain may be electrically coupled with the first channels. The first NS structure may yet comprise a first gate on the substrate in a first gate region between the first source and the first drain. The first gate may surround each of the first channels. The first NS structure may yet further comprise a first dielectric between the first channels and the first gate. The first dielectric may surround each of the first channels in the first gate region. The GAA device may further comprise a second nanosheet (NS) structure formed above a second logic area of the substrate different from the first logic area. The second NS structure may comprise one or more second nanosheets stacked above the substrate. The one or more second nanosheets may form second channels. A number of second channels may be N−M. 1≤M<N. The second NS structure may also comprise a second source on the substrate on a second source side of the second channels. The second source may be electrically coupled with the second channels. The second NS structure may further comprise a second drain on the substrate on a second drain side of the second channels opposite the second source side. The second drain may be electrically coupled with the second channels. The second NS structure may yet comprise a second gate on the substrate in a second gate region between the second source and the second drain. The second gate may surround each of the second channels. The second NS structure may yet further comprise a second dielectric between the second channels and the second gate. The second dielectric may surround each of the second channels in the second gate region. A number of first nanosheets may be N, and a number of second nanosheets may also be N. A lower most N−M second nanosheets may form the second channels.

Another exemplary gate-all-around (GAA) device is disclosed. The GAA device may comprise a substrate. The GAA device may also comprise a first nanosheet (NS) structure formed above a first logic area of the substrate. The first NS structure may comprise a plurality of first nanosheets stacked above the substrate. The plurality of first nanosheets may form first channels. A number of first channels may be N, N≥2. The first NS structure may also comprise a first source on the substrate on a first source side of the first channels. The first source may be electrically coupled with the first channels. The first NS structure may further comprise a first drain on the substrate on a first drain side of the first channels opposite the first source side. The first drain may be electrically coupled with the first channels. The first NS structure may yet comprise a first gate on the substrate in a first gate region between the first source and the first drain. The first gate may surround each of the first channels. The first NS structure may yet further comprise a first dielectric between the first channels and the first gate. The first dielectric may surround each of the first channels in the first gate region. The GAA device may further comprise a second nanosheet (NS) structure formed above a second logic area of the substrate different from the first logic area. The second NS structure may comprise one or more second nanosheets stacked above the substrate. The one or more second nanosheets may form second channels. A number of second channels may be N−M. 1≤M<N. The second NS structure may also comprise a second source on the substrate on a second source side of the second channels. The second source may be electrically coupled with the second channels. The second NS structure may further comprise a second drain on the substrate on a second drain side of the second channels opposite the second source side. The second drain may be electrically coupled with the second channels. The second NS structure may yet comprise a second gate on the substrate in a second gate region between the second source and the second drain. The second gate may surround each of the second channels. The second NS structure may yet further comprise a second dielectric between the second channels and the second gate. The second dielectric may surround each of the second channels in the second gate region. The second NS structure may in addition comprise second inner spacers and second upper spacers. The second inner spacers may be formed between the second source and the second gate and formed between the second drain and the second gate. The second upper spacers may be formed above an upper most second channel and formed on the second source and drain sides of the second gate. A dielectric constant of the second inner spacers may be different from a dielectric constant of the second upper spacers. A portion of the second inner spacers may be formed above the upper most second channel.

A method of fabricating a gate-all-around (GAA) device is disclosed. The method may comprise forming a substrate. The method may also comprise forming a first nanosheet (NS) structure above a first logic area of the substrate. The first NS structure may comprise a plurality of first nanosheets stacked above the substrate. The plurality of first nanosheets may form first channels. A number of first channels may be N, N≥2. The first NS structure may also comprise a first source on the substrate on a first source side of the first channels. The first source may be electrically coupled with the first channels. The first NS structure may further comprise a first drain on the substrate on a first drain side of the first channels opposite the first source side. The first drain may be electrically coupled with the first channels. The first NS structure may yet comprise a first gate on the substrate in a first gate region between the first source and the first drain. The first gate may surround each of the first channels. The first NS structure may yet further comprise a first dielectric between the first channels and the first gate. The first dielectric may surround each of the first channels in the first gate region. The method may further comprise a second nanosheet (NS) structure above a second logic area of the substrate different from the first logic area. The second NS structure may comprise one or more second nanosheets stacked above the substrate. The one or more second nanosheets may form second channels. A number of second channels may be N−M, 1≤M<N. The second NS structure may also comprise a second source on the substrate on a second source side of the second channels. The second source may be electrically coupled with the second channels. The second NS structure may further comprise a second drain on the substrate on a second drain side of the second channels opposite the second source side. The second drain may be electrically coupled with the second channels. The second NS structure may yet comprise a second gate on the substrate in a second gate region between the second source and the second drain. The second gate may surround each of the second channels. The second NS structure may yet further comprise a second dielectric between the second channels and the second gate. The second dielectric may surround each of the second channels in the second gate region. A number of first nanosheets may be N, and a number of second nanosheets may also be N. A lower most N−M second nanosheets may form the second channels.

Another method of fabricating a gate-all-around (GAA) device is disclosed. The method may comprise forming a substrate. The method may also comprise forming a first nanosheet (NS) structure above a first logic area of the substrate. The first NS structure may comprise a plurality of first nanosheets stacked above the substrate. The plurality of first nanosheets may form first channels. A number of first channels may be N. N≥2. The first NS structure may also comprise a first source on the substrate on a first source side of the first channels. The first source may be electrically coupled with the first channels. The first NS structure may further comprise a first drain on the substrate on a first drain side of the first channels opposite the first source side. The first drain may be electrically coupled with the first channels. The first NS structure may yet comprise a first gate on the substrate in a first gate region between the first source and the first drain. The first gate may surround each of the first channels. The first NS structure may yet further comprise a first dielectric between the first channels and the first gate. The first dielectric may surround each of the first channels in the first gate region. The method may further comprise a second nanosheet (NS) structure above a second logic area of the substrate different from the first logic area. The second NS structure may comprise one or more second nanosheets stacked above the substrate. The one or more second nanosheets may form second channels. A number of second channels may be N−M. 1≤M<N. The second NS structure may also comprise a second source on the substrate on a second source side of the second channels. The second source may be electrically coupled with the second channels. The second NS structure may further comprise a second drain on the substrate on a second drain side of the second channels opposite the second source side. The second drain may be electrically coupled with the second channels. The second NS structure may yet comprise a second gate on the substrate in a second gate region between the second source and the second drain. The second gate may surround each of the second channels. The second NS structure may yet further comprise a second dielectric between the second channels and the second gate. The second dielectric may surround each of the second channels in the second gate region. The second NS structure may in addition comprise second inner spacers and second upper spacers. The second inner spacers may be formed between the second source and the second gate and formed between the second drain and the second gate. The second upper spacers may be formed above an upper most second channel and formed on the second source and drain sides of the second gate. A dielectric constant of the second inner spacers may be different from a dielectric constant of the second upper spacers. A portion of the second inner spacers may be formed above the upper most second channel.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1A illustrates an example of nanosheet wafer divided into logic areas in accordance with one or more aspects of the disclosure.

FIG. 1B illustrates a top view of a gate-all-around (GAA) device in accordance with one or more aspects of the disclosure.

FIG. 2A illustrates cross-sectional views of a first embodiment of a GAA device along Y-cut through line of FIG. 1B for a first (N) nanosheet structure and a second (N−M) nanosheet structure in accordance with one or more aspects of the disclosure.

FIG. 2B illustrates cross-sectional views of the first embodiment of the GAA device along X-cut through line of FIG. 1B for the first (N) nanosheet structure and the second (N−M) nanosheet structure in accordance with one or more aspects of the disclosure.

FIG. 3 illustrates an example of a nanosheet wafer for fabricating the first embodiment of the GAA device in accordance with one or more aspects of the disclosure.

FIGS. 4A-8B illustrate examples of stages of fabricating the first embodiment of the GAA device with early patterning in accordance with one or more aspects of the disclosure.

FIG. 9A illustrates cross-sectional views of a second embodiment of a GAA device along Y-cut through line of FIG. 1B for a first (N) nanosheet structure and a second (N−M) nanosheet structure in accordance with one or more aspects of the disclosure.

FIG. 9B illustrates cross-sectional views of the second embodiment of the GAA device along X-cut through line of FIG. 1B for the first (N) nanosheet structure and the second (N−M) nanosheet structure in accordance with one or more aspects of the disclosure.

FIGS. 10A-10E illustrate examples of stages of providing a nanosheet wafer for fabricating the second of GAA device in accordance with one or more aspects of the disclosure.

FIGS. 11A-15B illustrate examples of stages of fabricating the second embodiment of the GAA device with early patterning in accordance with one or more aspects of the disclosure.

FIGS. 16-19 illustrate flow charts of example methods of manufacturing GAA devices in accordance with one or more aspects of the disclosure.

FIG. 20 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising.” “includes,” and/or “including.” when used herein, specify the presence of stated features, integers, steps, operations, elements, and/or components, but do not preclude the presence or addition of one or more other features, integers, steps, operations, elements, components, and/or groups thereof.

As indicated above, GAA devices typically have a fixed ribbon or nanosheet (NS) count, e.g., 3 or 4. The nanosheets—once processed—can function as channels of transistors conducting current between sources and drains. Thus, the number of nanosheets per device is typically a fundamental limitation to achieving lowest power. There is a baseline sheet count N (e.g., 3 or 4) in GAA technology, and this number is normally not manipulated. However, for power/performance area (PPA), especially for lowering power, it would be desirable to manipulate the sheet count.

To address these and other issues of conventional GAA device, it is proposed to provide additional logic area areas with N−M nanosheets on the same GAA wafer. This can be achieved by using extra masks (typically just one) and few extra processing steps. This is in addition to the base N nanosheet device offering. The proposed extended capability provides a novel way to drive the design to lower power-through both reduced cell level capacitance as well as reduced leakage. The proposed technique can be scalable to work with various starting number of nanosheet stack, i.e., N can be any number.

The proposed technique can easily scale to have multiple logic areas on the same wafer. For example, For example, in a 4-stack GAA technology (N=4), one can make 3-stack device area (M=1). By repeating the same process, a 2-stack device area (M=2) can also be made on the same wafer, enabling 3 unique stack devices. This can provide a wide range of effective width devices for design options. It should be noted that the extra process involved is simple and mature. That is, no new tool purchase would be required. Also, no new material need be introduced.

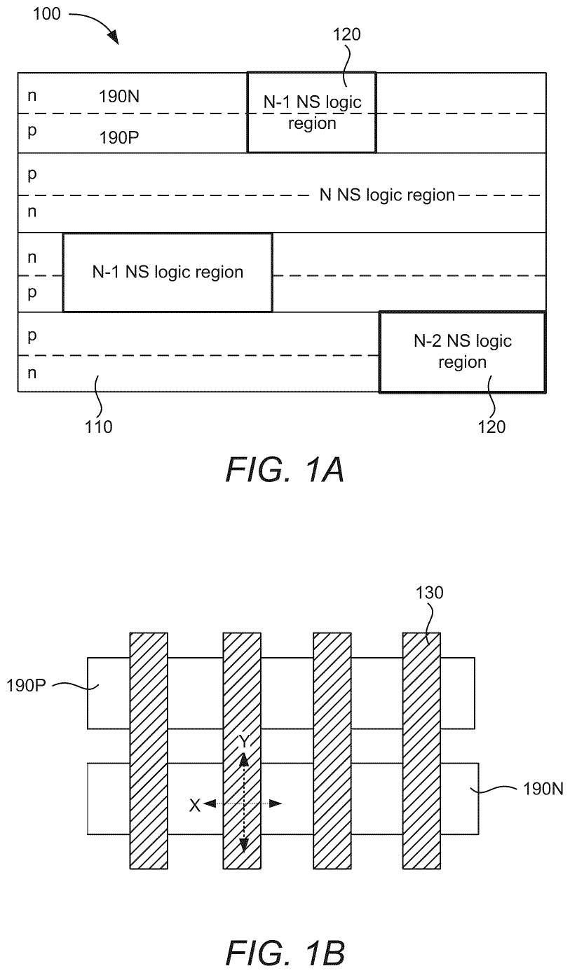

FIG. 1A illustrates an example of nanosheet wafer 100 divided into logic areas in accordance with one or more aspects of the disclosure. In particular, a top view of an example design implementation is shown. In FIG. 1A, four rows of the nanosheet wafer 100 is shown in which each row may include an N diffusion 190N and a P diffusion 190P. The rows here can refer to standard cell rows in place and route for logic design.

The nanosheet wafer 100 may include multiple logic regions or areas. The example nanosheet wafer 100 is shown to include N logic area, N−1 logic area, and N−2 logic area. The nanosheet wafer 100 has a baseline N nanosheets. The devices (e.g., transistors) in the N logic area may use all N nanosheets (e.g., as channels of the transistor). The N logic area may be for those devices that require highest performance, e.g., speed.

However, in the N−1 logic area of the same wafer 100, the number of nanosheets may be manipulated, i.e., reduced by one so that the devices (e.g., transistors) in the N−1 logic area where N−1 channels are sufficient. With less number of channels, power consumption as well as undesirable capacitance can be reduced. Further, in the N−2 logic area of the wafer 100, the number of nanosheets may be reduced even further, to thereby even further minimize power consumption and undesirable capacitance. This area may be reserved for those devices whose speed is of minor concern.

Thus, in general, it may be said that a nanosheet wafer (e.g., wafer 100) may be divided into a plurality of logic areas. There may be a baseline logic area where N nanosheets are utilized for the devices, N≥2. There may also be one or more logic areas where the number of nanosheets used for devices is reduced by M. That is, the number of nanosheets in such areas is N−M, 1≤M<N. There can be any number of such areas.

FIG. 1B a top view of a gate-all-around (GAA) device in accordance with one or more aspects of the disclosure. This is a simplified view. The example GAA device includes the N and P diffusions 190N and 190P. These may serve as portions of a field effect transistor (FET—e.g., NFET, PFET). The GAA device may also include gates 130. In an aspect, the gates 130 may be formed of metal.

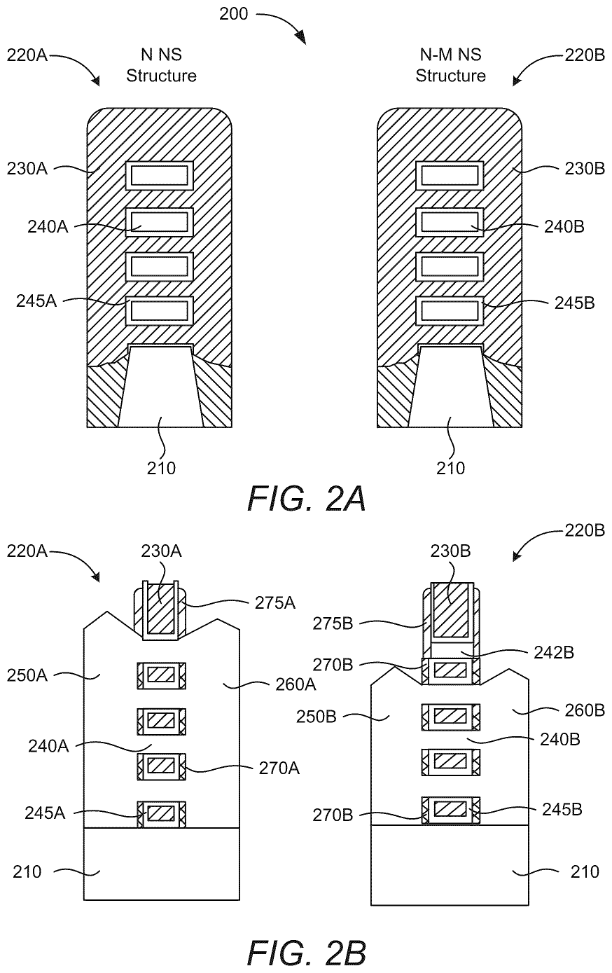

FIG. 2A illustrates cross-sectional views of a first embodiment of a GAA device along Y-cut through line of FIG. 1B for an N nanosheet structure 220A and an N−M nanosheet structure 220B in accordance with one or more aspects of the disclosure. FIG. 2B illustrates cross-sectional views of the first embodiment of the GAA device along X-cut through line of FIG. 1B for the N nanosheet structure 220A and the N−M nanosheet structure 220B in accordance with one or more aspects of the disclosure.

As seen, the GAA device 200 may include a substrate 210, a first NS structure 220A formed above a first logic area 110 (e.g., see FIG. 1A) of the substrate 210, and a second NS structure 220B formed above a second logic area 120 of the substrate 210. The first and second logic area 110, 120 may be different. It may be assumed that the first and second logic area 110, 120 are logic areas of a same nanosheet wafer. Thus, the first and second NS structures 220A, 220B also may be assumed to be formed in a same single nanosheet wafer, such as the nanosheet wafer 100.

The first NS structure 220A may be the NS structure formed in the N logic area (first logic area) 110. The first NS structure 220A may include a plurality of first nanosheets 240A stacked above the substrate 210. The first nanosheets 240A may form first channels 240A (e.g., of a transistor device). The first nanosheets, and hence the first channels, may be formed from silicon (Si) or other semiconductor materials such as silicon germanium (SiGe), gallium arsenide (GaAs), and so on. The number of first channels 240A may be N, where N≥2. Note that N is the number of nanosheets of the nanosheet wafer. That is, in the first NS structure 220A, all of the baseline N nanosheets/ribbons of the wafer may be used to form the first channels of the device. Thus, in this instance, the first nanosheets and the first channels may be synonymous with each other within the first NS structure 220A.

The first NS structure may also include a first source 250A and a first drain 260A. It should be noted that structurally, the first source and drain 250A, 260A may be very similar to each other. That is, either can be used as a source and other can be used as a drain. For example, both can be grown epitaxially. However, for case of reference, 250A will be used to refer to the first source and 260A will be used to refer to the first drain.

The first source 250A may be formed on the substrate 210 on a first source side of the first channels 240A. The first source 250A may be electrically coupled with the first channels 240A. For example, the first source 250A may be in direct contact with the first channels 240A on the first source side.

The first drain 260A may be formed on the substrate 210 on a first drain side of the first channels 240A. The first drain side may be opposite the first source side. The first drain 260A may be electrically coupled with the first channels 240A. For example, the first drain 260B may be in direct contact with the first channels 240A on the first drain side.

The first NS structure may further include a first gate 230A formed on the substrate 210 in a first gate region, which may be between the first source 250A and the first drain 260A. As seen, the first gate 230A may surround each of the first channels 240A in the first gate region. The first gate 230A may be formed from a first metal (e.g., tungsten (W), titanium aluminide (TiAl), titanium nitride (TiN), etc.).

A first dielectric 245A may be formed between the first channels 240A and the first gate 230A. In the first gate region, the first dielectric 245A may surround each of the first channels 240A. The first dielectric 245A may be a high-k dielectric. When a voltage is applied to the first gate 230A, the first channels 240A may electrically couple the first source and drain 250A. 260A.

The first NS structure may additionally include first inner spacers 270A and first upper spacers 275A. The first inner spacers 270A may be formed in the first gate region between the first source 250A and the first gate 230A, and between the first drain 260A and the first gate 230A. The first inner spacers 270A may be formed from a dielectric material.

The first upper spacers 275A may be formed above an upper most first channel 240A and on the first source and drain sides of the first gate 230A. In particular, the first upper spacers 275A may be formed on the upper most portion of the first gate 230A. If the upper surface of the first gate 230A is at a first height, then in an aspect, upper surfaces of the first upper spacers 275 may be at the same first height.

The first upper spacers 275A may be formed from a dielectric material. In an aspect, the first upper spacers 275A and the first inner spacers 270A may be formed from different materials. For example, their respective dielectric constants may be different. As an illustration, the dielectric constant of the first inner spacers 270A may be lower than the dielectric constant of the first upper spacers 275A. The first inner spacers 270A in the first gate region may be formed vertically below the first upper spacers 275A. The first inner spacers 270A may be alternatively stacked with the first channels 240A in the first gate region. That is, first inner spacers 270A may be alternatively stacked with the nanosheets (e.g., first nanosheets 240A) in the first gate region.

The second NS structure 220B may be the NS structure formed in the N−M logic area (second logic area) 120. The second NS structure 220B may include a one or more second nanosheets 240B stacked above the substrate 210. The second nanosheets 240B may form second channels 240B (e.g., of a transistor device). The number of second channels 240B may be N−M, where 1≤M<N. In an aspect, N−M may be a part of the baseline N nanosheets of the wafer. That is, in the second NS structure 220B, N−M of the baseline N nanosheets/ribbons of the wafer may be used to form the second channels of the device. Thus, in this instance, the second channels may be synonymous with the N−M second nanosheets. There may be M nanosheets 242B that are not used as channels in the second NS structure 220B. In an aspect, the lower most N−M second nanosheets 240B may be used as the second channels and the M upper most second nanosheets 242B may be left floating. The N second nanosheets (which includes the N−M second channels 240B and the M upper most second nanosheets 242B) may be formed from Si.

The second NS structure may also include a second source 250B and a second drain 260B. It should be noted that structurally, the second source and drain 250B, 260B may be very similar to each other. That is, either can be used as a source and other can be used as a drain. For example, both can be grown epitaxially. However, for ease of reference, 250A will be used to refer to the second source and 250B will be used to refer to the second drain.

The second source 250B may be formed on the substrate 210 on a second source side of the second channels 240B. The second source 250B may be electrically coupled with the second channels 240B. For example, the second source 250B may be in direct contact with the second channels 240B on the second source side.

The second drain 260B may be formed on the substrate 210 on a second drain side of the second channels 240B. The second drain side may be opposite the second source side.

The second drain 260B may be electrically coupled with the second channels 240B. For example, the second drain 260B may be in direct contact with the second channels 240B on the second drain side.

The second NS structure may further include a second gate 230B formed on the substrate 210 in a second gate region, which may be between the second source 250B and the second drain 260B. As seen, the second gate 230B may surround each of the second channels 240B in the second gate region. The second gate 230B may be formed from a second metal (e.g., Cu, W, etc.). The first and second gates 230A, 230B may be formed from a same metal or from different metals. In an aspect, upper surfaces of the first gate 230A and the second gate 230B may be coplanar. That is, the first and second gates 230A, 230B may be at a same height.

A second dielectric 245B may be formed between the second channels 240B and the second gate 230B. In the second gate region, the second dielectric 245B may surround each of the second channels 240B. The second dielectric 245B may be a high-k dielectric. The first and second dielectrics may be formed from same or different dielectric materials. When a voltage is applied to the second gate 230B, the second channels 240B may electrically couple the second source and drain 250B, 260B.

The second NS structure may additionally include second inner spacers 270B and second upper spacers 275B. The second inner spacers 270B may be formed in the second gate region between the second source 250A and the second gate 230B, and between the second drain 260B and the second gate 230B. The second inner spacers 270B may be formed from a dielectric material, which may be same or different from the dielectric material of the first inner spacers 270A.

The second upper spacers 275B may be formed above an upper most second channel 240B and on the second source and drain sides of the second gate 230B. In particular, the second upper spacers 275B may be formed on the upper most portion of the second gate 230B. If the upper surface of the second gate 230B is at a second height, then in an aspect, upper surfaces of the second upper spacers 275 may be at the same second height. In an aspect, the first and second heights may be the same.

The second upper spacers 275B may be formed from a dielectric material, which may be same or different from the dielectric material of the first upper spacers 275A. In an aspect, a dielectric constant of the second inner spacers 270B may be different from a dielectric constant of the second upper spacers 275B. For example, the dielectric constant of the second inner spacers 270B may be lower than that of the second upper spacers 275B. The second inner spacers 270B in the second gate region may be formed vertically below the second upper spacers 275B. The second inner spacers 270B may be alternatively stacked with the second channels 240B in the second gate region. That is, second inner spacers 270B may be alternatively stacked with the nanosheets (e.g., second nanosheets 240B) in the second gate region.

Note that in the second NS structure region 220B, upper most second inner spacers 270B may be formed on the upper most second channel 240B, and the second upper spacers 275B may be formed on upper most second inner spacers 270B. For example, they may be in direct contact. Also, the second upper spacers 275B may also be formed on the second source and drain sides of the floating nanosheet 242B. In general, it may be said that the second upper spacers 275B may be formed on the second source and drain sides of the upper most M nanosheets 242B, which may be floating.

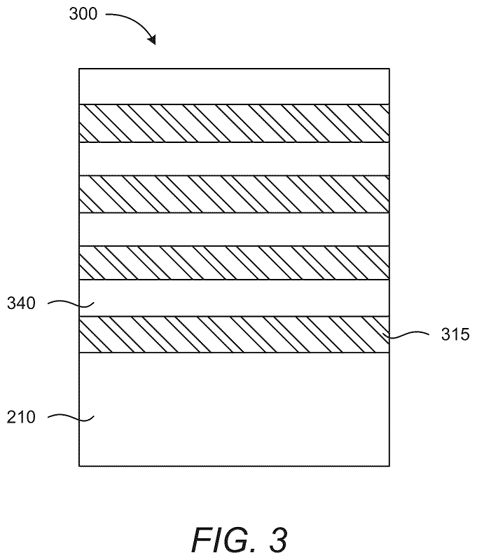

FIG. 3 illustrates an example of a nanosheet wafer 300 for fabricating the first embodiment of the GAA device in accordance with one or more aspects of the disclosure. As seen, the initial nanosheet wafer 300 may include the substrate 210, a plurality of dummy layers 315 (e.g., formed from silicon germanium (SiGe)), and a plurality of nanosheets 340 (e.g., formed from Si). The dummy layers 315 and the nanosheets 340 may be alternatively stacked above the substrate 210. A portion of the nanosheet wafer 300 may be the first logic area (upon which the first NS structure 220A may be formed) and another portion may be the second logic area (upon which the second NS structure 220B may be formed).

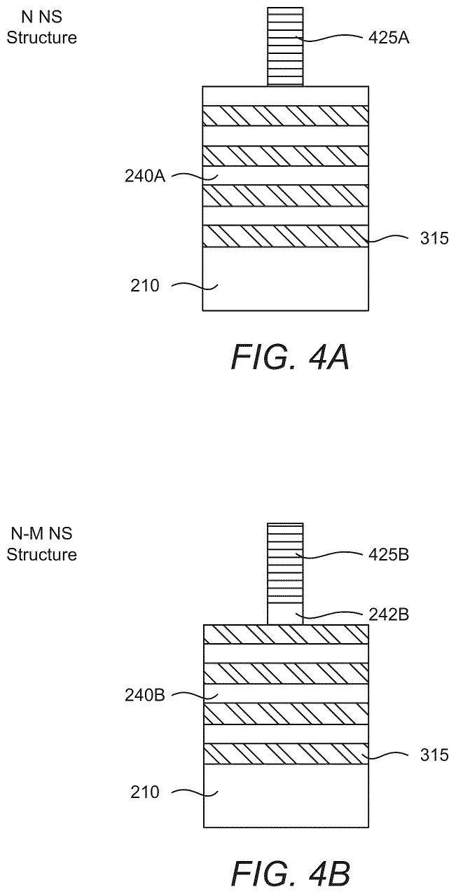

FIGS. 4A-8B illustrate examples of stages of fabricating the first embodiment of the GAA device with early patterning in accordance with one or more aspects of the disclosure. The flow process to fabricate the first embodiment may include the following steps:
a. Dummy layer/nanosheet (e.g., SiGe/Si) stack.
b. Nanosheet patterning.
c. Gate patterning and etch stop on top nanosheet.
d. Extra mask (cover N-stack area, expose N−1 area).
e. Additional etch to remove top nanosheet and stop on dummy layer (e.g., SiGe layer).
f. Optionally repeat c and d to make N−2, N−3, etc. regions, i.e., to make N−M regions.
g. Spacer formation.
h. NFET/PFET epitaxial formation.
i. Source/drain implantation.
j. Poly gate strip and dummy layer release.
k. HK and metal gate formation.
l. Contact formation.
m. Middle-of-line (MOL) process.
n. back end-of-line (BEOL) process.

FIGS. 4A-8B generally illustrate various stages of a front end-of-line (FEOL) processes (e.g., steps a-l). The processing stages illustrated in FIGS. 4A-8B may be referred to as “late patterning” process in that the process to manipulate the second logic area occurs after the gate patterning the baseline wafer 300. FIGS. 4A, 5A, 6A, 7A and 8A illustrate stages related to the formation of the first NS structure 220A, and FIGS. 4B, 5B, 6B, 7B and 8B illustrate stages related to the formation of the second NS structure 220B. In these figures, M may be assumed to be 1. That is, the second NS structure 220B may be an N−1 NS structure. However, it will be relatively straightforward to apply the illustrated processing stages to generic N−M NS structures.

FIG. 4A illustrates a stage in which a first dummy gate 425A may be formed on the upper most first nanosheet 240A. The first dummy gate 425A may be formed using a dummy gate mask (not shown). Note that the upper most first nanosheet 240A will also become one of the first channels.

FIG. 4B illustrates a stage in which a second dummy gate 425B may be formed on the upper most second nanosheet 242B. In an aspect, the dummy gate mask may be used to also to form the second dummy gate 425B. Thereafter, another mask (also not shown) may be used to etch the top nanosheet 240B in the second NS structure.

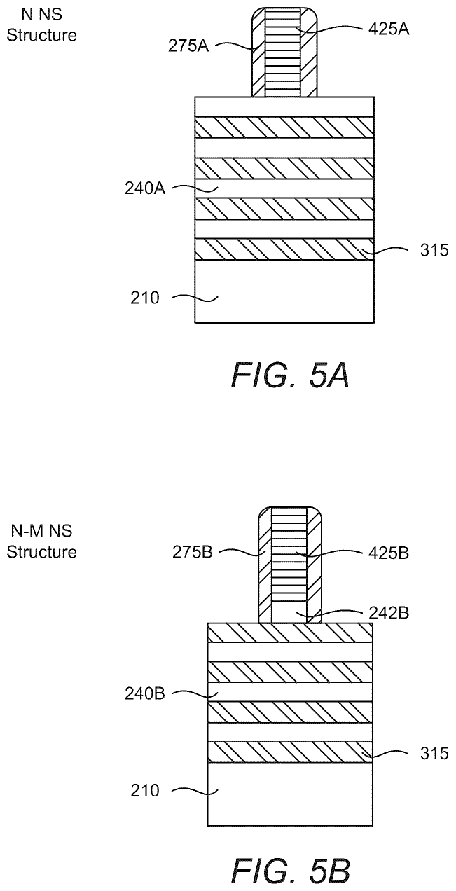

Note that the dummy gate patterning step may be common to both N and N−M regions. The extra mask is only used to make the N−M regions (to etch N−M nanosheets). All of the remaining processes (as illustrated in FIGS. 5A-8B) may be common between the N and N−M regions at each of the stages. That is, subsequent to forming the first and second dummy gates 425A, 425B, the extra mask may be used to etch the second logic area to remove the upper most M nanosheets on the second source and drain sides. If multiple upper most M nanosheets are removed (e.g., M≥2), then M−1 upper most dummy layers 315 may also be removed. Within the second gate region, the dummy layers 315 and the nanosheets 240B may be left alone

After forming the first dummy gate 425A, FIG. 5A illustrates a stage in which the first upper spacers 275A may be formed. The first upper spacers 275A may be formed above the upper most first channel 240A and on the first source and drain sides of the first dummy gate 425A.

After forming the second dummy gate 425B, FIG. 5B illustrates a stage in which the second upper spacers 275B may be formed. The second upper spacers 275B may be formed above the upper most dummy layer 315 and on the second source and drain sides of the second dummy gate 425B. The second upper spacers 275B may also be formed and on the second source and drain sides of the upper most M nanosheets 242B. These upper most M nanosheets 242B may be left floating. In an aspect, the first and second upper spacers 275A. 275B may be formed concurrently.

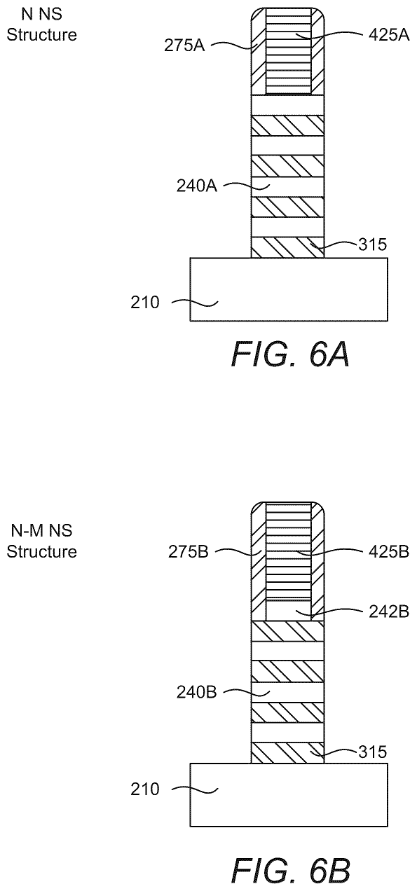

FIG. 6A illustrates a stage in which the first logic area may be etched to form recesses in the first source and drain sides. Through such etching, the substrate 210 may be exposed on both the first source and drain sides.

FIG. 6B illustrates a stage in which the second logic area may be etched to form recesses in the second source and drain sides. Through such etching, the substrate 210 may be exposed on both the second source and drain sides. In an aspect, the first and second logic areas may be etched concurrently to expose the substrate 210.

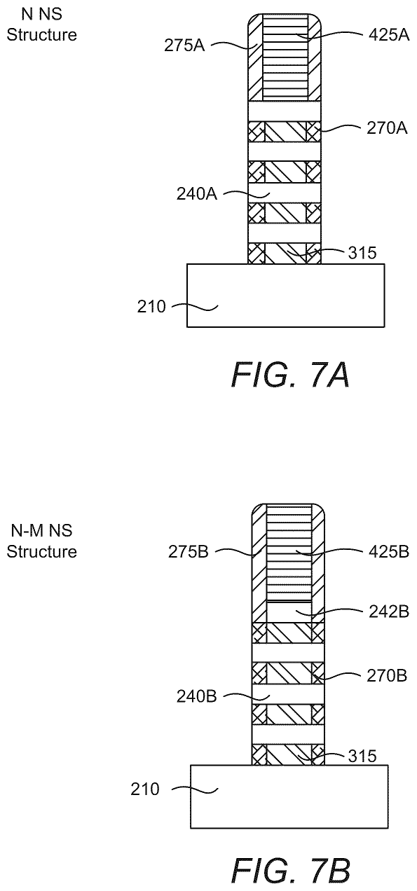

FIG. 7A illustrates a stage in which outer portions of the dummy layer 315 in the first gate region may be removed and replaced with the first inner spacers 270A vertically below the first upper spacers 275A. The first inner spacers 270A may be alternatively stacked with the nanosheets (e.g., first nanosheets or channels 240A) in the first gate region.

FIG. 7B illustrates a stage in which outer portions of the dummy layer 315 in the second gate region may be removed and replaced with the second inner spacers 270B vertically below the second upper spacers 275B. The second inner spacers 270B may be alternatively stacked with the nanosheets (e.g., second nanosheets or channels 240B) in the second gate region. In an aspect, the first and second inner spacers 270A, 270B may be formed concurrently.

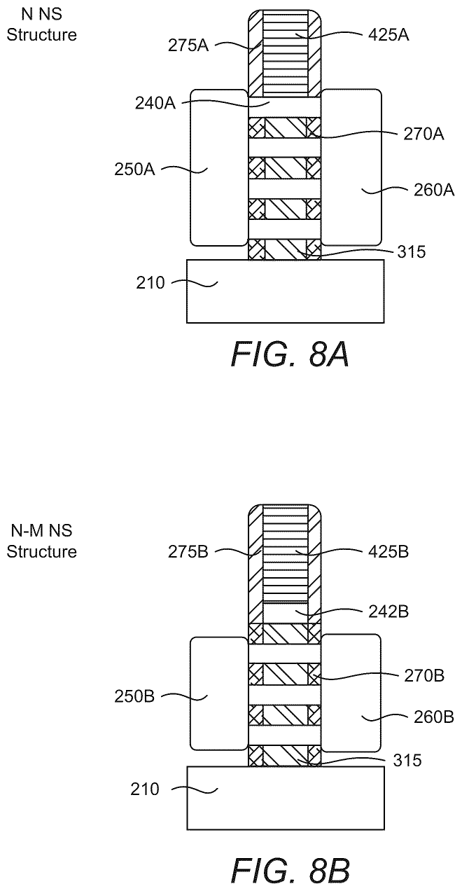

FIG. 8A illustrates a stage in which the first source and drain 250A, 260A may be formed. For example, they may be grown epitaxially. The first source and drain 250A, 260A may be formed to be coupled with (e.g., in direct contact with) the first channels 240A.

FIG. 8B illustrates a stage in which the second source and drain 250B, 260B may be formed. For example, they may be grown epitaxially. The second source and drain 250B, 260B may be formed to be coupled with (e.g., in direct contact with) the second channels 240B. Note that the second source and drain 250B, 260B are NOT coupled with the upper most M nanosheets 242B. In an aspect, the first and second sources 250A, 250B, and first and second drains 260A, 260B may be formed concurrently.

While not shown, thereafter, the first and second dummy gates 425A, 425B as well as the dummy layers 315 in the gate region may be stripped or otherwise removed. The first gate 230A may be formed in the first gate region in place of the removed first dummy gate 425A and the dummy layer 315. Similarly, the second gate 230B may be formed in the second gate region in place of the removed second dummy gate 425B and the dummy layer 315.

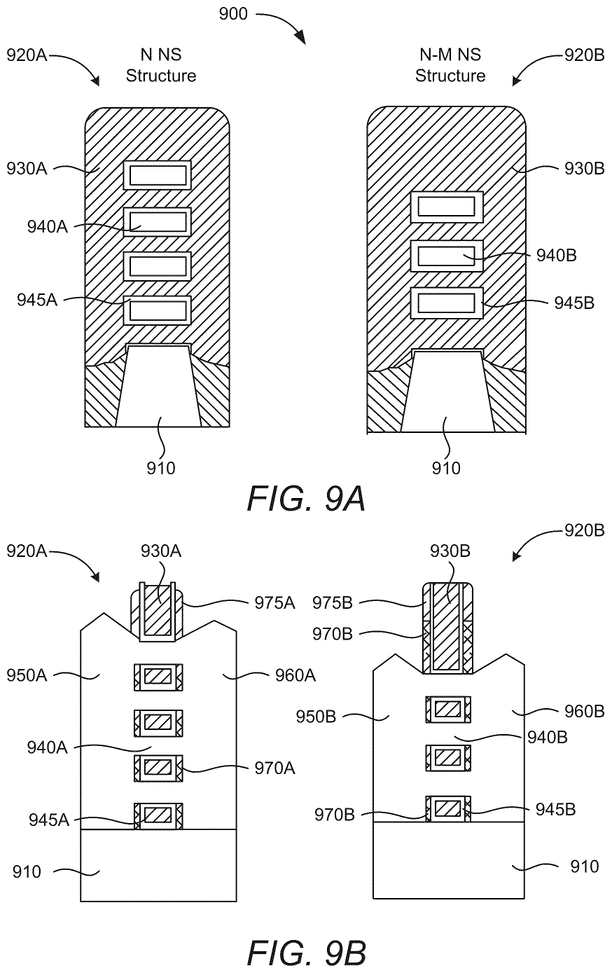

FIG. 9A illustrates cross-sectional views of a second embodiment of a GAA device along Y-cut through line of FIG. 1B for a first (N) NS structure 920A and a second (N−M) NS structure 920B in accordance with one or more aspects of the disclosure. FIG. 9B illustrates cross-sectional views of the second embodiment of the GAA device along X-cut through line of FIG. 1B for the first NS structure 920A and the second NS structure 920B in accordance with one or more aspects of the disclosure.

As seen, the GAA device 900 may include a substrate 910, a first NS structure 920A formed above a first logic area 110 (e.g., see FIG. 1A) of the substrate 910, and a second NS structure 920B formed above a second logic area 120 of the substrate 910.

The first NS structure 920A may be the NS structure formed in the N logic area (first logic area) 110. The first NS structure 920A may be very similar to the first NS structure 220A (see FIGS. 2A and 2B). That is, the first NS structure 920A may include a plurality of first nanosheets 940A stacked above the substrate 910. The first nanosheets 940A may form first channels 940A. The first nanosheets, and hence the first channels, may be formed from Si. The number of first channels 940A may be N, where N≥2. In the first NS structure 920A, all of the baseline N nanosheets/ribbons of the initial wafer may be used to form the first channels of the device.

The first NS structure may also include a first source 950A and a first drain 960A. Again, structurally, the first source and drain 950A, 960A may be very similar to each other. The first source 950A may be formed on the substrate 910 on a first source side of the first channels 940A. The first source 950A may be electrically coupled with the first channels 940A, e.g., they may be in direct contact with the first channels 940A on the first source side.

The first drain 960A may be formed on the substrate 910 on a first drain side of the first channels 940A. The first drain 960A may be electrically coupled with the first channels 940A, e.g., they may be in direct contact with the first channels 940A on the first drain side.

The first NS structure may further include a first gate 930A formed on the substrate 910 in a first gate region, which may be between the first source 950A and the first drain 960A. The first gate 930A may surround each of the first channels 940A in the first gate region. The first gate 930A may be formed from a first metal (e.g., Cu, W, etc.).

A first dielectric 945A may be formed between the first channels 940A and the first gate 930A. In the first gate region, the first dielectric 945A (e.g., a high-k dielectric) may surround each of the first channels 940A. When a voltage is applied to the first gate 930A, the first channels 940A may electrically couple the first source and drain 950A, 960A.

The first NS structure may additionally include first inner spacers 970A and first upper spacers 975A. The first inner spacers 970A may be formed in the first gate region between the first source 950A and the first gate 930A, and between the first drain 960A and the first gate 930A. The first inner spacers 970A may be formed from a dielectric material.

The first upper spacers 975A may be formed above an upper most first channel 940A and on the first source and drain sides of the first gate 930A. In particular, the first upper spacers 975A may be formed on the upper most portion of the first gate 930A. If the upper surface of the first gate 930A is at a first height, then in an aspect, upper surfaces of the first upper spacers 975 may be at the same first height.

The first upper spacers 975A may be formed from a dielectric material. In an aspect, the first upper spacers 975A and the first inner spacers 970A may be formed from different materials. For example, their respective dielectric constants may be different. As an illustration, the dielectric constant of the first inner spacers 970A may be lower than the dielectric constant of the first upper spacers 975A. The first inner spacers 970A in the first gate region may be formed vertically below the first upper spacers 975A. The first inner spacers 970A may be alternatively stacked with the first channels 940A in the first gate region. That is, first inner spacers 970A may be alternatively stacked with the nanosheets (e.g., first nanosheets 940A) in the first gate region.

The second NS structure 920B may be the NS structure formed in the N−M logic area (second logic area) 120. The second NS structure 920B may be different from the second NS structure 220B (see FIGS. 2A and 2B). In particular, there may be NO nanosheets that are floating. That is, in the second embodiment, there may be N−M second nanosheets 940B all of which form the second channels.

The second NS structure 920B may include a one or more second nanosheets 940B stacked above the substrate 910. The second nanosheets 940B may form second channels 940B. The number of second channels 940B may be N−M, where 1≤M<N.

The second NS structure may also include a second source 950B and a second drain 960B. Structurally, the second source and drain 950B, 960B may be very similar to each other. The second source 950B may be formed on the substrate 910 on a second source side of the second channels 940B. The second source 950B may be electrically coupled with the second channels 940B, e.g., they may be in direct contact with the second channels 940B on the second source side.

The second drain 960B may be formed on the substrate 910 on a second drain side of the second channels 940B. The second drain side may be opposite the second source side. The second drain 960B may be electrically coupled with the second channels 940B, e.g., they may be in direct contact with the second channels 940B on the second drain side.

The second NS structure may further include a second gate 930B formed on the substrate 910 in a second gate region in between the second source 950B and the second drain 960B. The second gate 930B may surround each of the second channels 940B in the second gate region. The second gate 930B may be formed from a second metal (e.g., Cu, W, etc.). The first and second gates 930A, 930B may be formed from a same metal or from different metals. In an aspect, upper surfaces of the first gate 930A and the second gate 930B may be coplanar. That is, the first and second gates 930A, 930B may be at a same height.

A second dielectric 945B may be formed between the second channels 940B and the second gate 930B. In the second gate region, the second dielectric 945B may surround each of the second channels 940B. The second dielectric 945B may be a high-k dielectric. The first and second dielectrics may be formed from same or different dielectric materials. When a voltage is applied to the second gate 930B, the second channels 940B may electrically couple the second source and drain 950B, 960B.

The second NS structure may additionally include second inner spacers 970B and second upper spacers 975B. The second inner spacers 970B may be formed in the second gate region between the second source 950A and the second gate 930B, and between the second drain 960B and the second gate 930B. The second inner spacers 970B may be formed from a dielectric material, which may be same or different from the dielectric material of the first inner spacers 970A.

The second upper spacers 975B may be formed above an upper most second channel 940B and on the second source and drain sides of the second gate 930B. In particular, the second upper spacers 975B may be formed on the upper most portion of the second gate 930B. If the upper surface of the second gate 930B is at a second height, then in an aspect, upper surfaces of the second upper spacers 975 may be at the same second height. In an aspect, the first and second heights may be the same.

The second upper spacers 975B may be formed from a dielectric material, which may be same or different from the dielectric material of the first upper spacers 975A. In an aspect, a dielectric constant of the second inner spacers 970B may be different from a dielectric constant of the second upper spacers 975B. For example, the dielectric constant of the second inner spacers 970B may be lower than that of the second upper spacers 975B. The second inner spacers 970B in the second gate region may be formed vertically below the second upper spacers 975B. The second inner spacers 970B may be alternatively stacked with the second channels 940A in the second gate region. That is, second inner spacers 970B may be alternatively stacked with the nanosheets (e.g., second nanosheets 940B) in the second gate region.

Note that in the second NS structure region 920B, upper most second inner spacers 970B may be formed on the upper most second channel 940B, and the second upper spacers 975B may be formed on upper most second inner spacers 970B. For example, they may be in direct contact.

The second embodiment of the GAA device 900 may be fabricated with early patterning process. As will be seen further below, in the early patterning process, the manipulation of the second logic area may occur prior to, i.e., earlier than the gate patterning. The flow process to fabricate the second embodiment may include the following steps:
a. Dummy layer/nanosheet (e.g., SiGe/Si) stack.
b. Mask step to expose N−1 area, etch off upper most nanosheet.
c. Form spacer isolation and grow extra sacrificial dummy layer on N−1 area.
d. Optionally repeat b and c to make N−2, N−3, etc. regions, i.e., to make N−M regions.
e. Nanosheet patterning.
f. Gate patterning and upper spacer formation.
g. S/D recess and inner spacer formation.
h. NFET/PFET epitaxial formation.
i. Source/drain implantation.
j. Poly gate strip and dummy layer release.
k. HK and metal gate formation.
l. Contact formation.
m. Middle-of-line (MOL) process.
n. back end-of-line (BEOL) process.

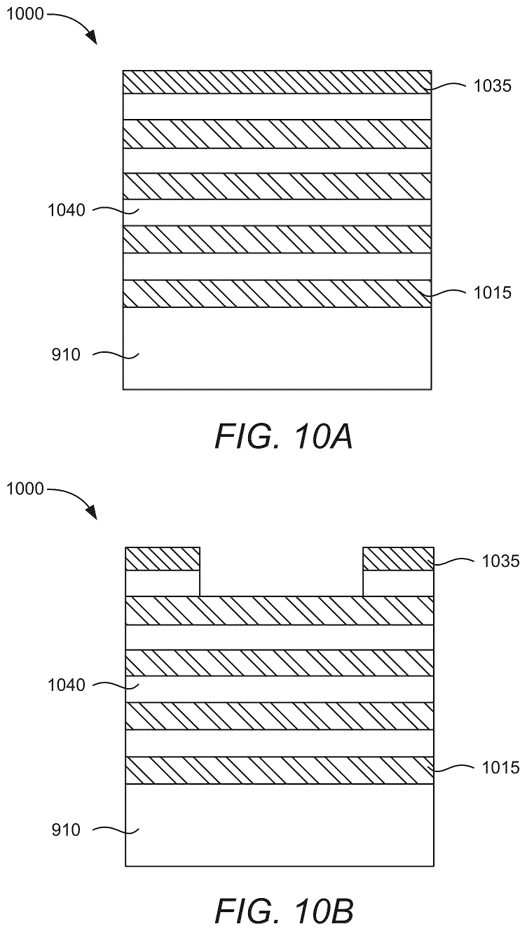

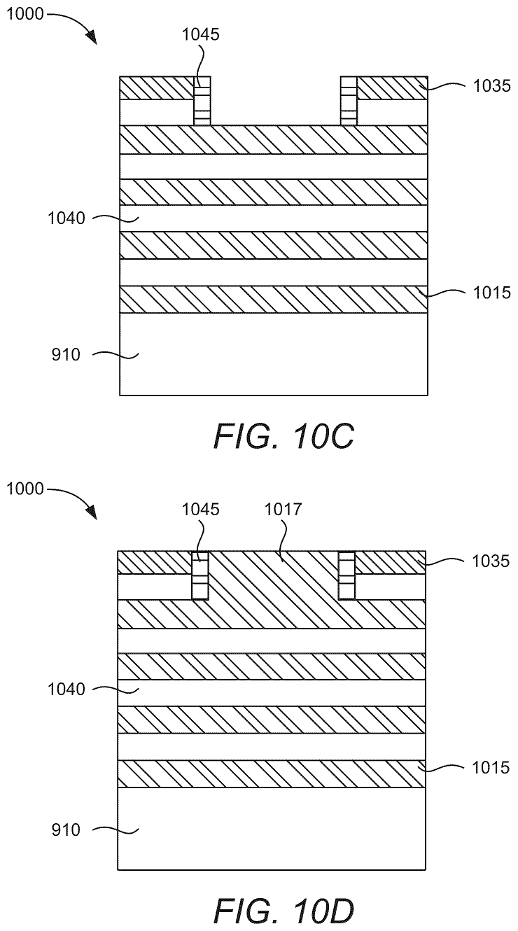

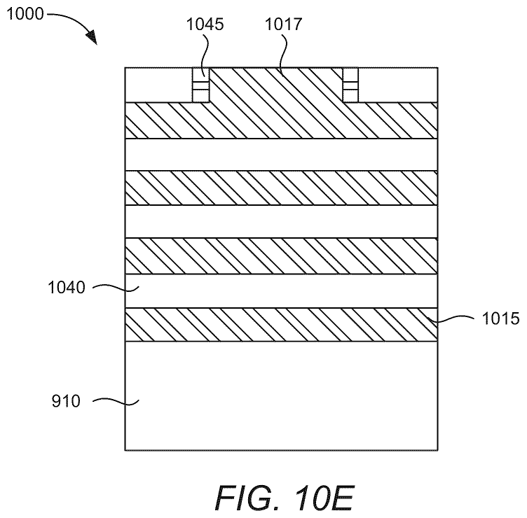

As indicated above, the initial wafer may be processed, prior to the gate formation, to form the N−M nanosheets in the second logic area 120. This is illustrated in FIGS. 10A-10E, which illustrate examples of providing a nanosheet wafer for fabricating the second GAA device 900. The stages illustrated in FIGS. 10A-10E may correspond to steps a, b, c and d of the early patterning process flow. In these figures, it may be assumed that initially, a baseline nanosheet wafer 1000 with N nanosheets throughout the entirety of the nanosheet wafer is provided.

FIG. 10A illustrates a stage in which a masking material (e.g., photoresist) may be disposed on the wafer 1000. As seen, the nanosheet wafer 1000 may include the substrate 910, a plurality of dummy layers 1015 (e.g., formed from SiGe), and a plurality of nanosheets 1040 (e.g., formed from Si). The dummy layers 1015 and the nanosheets 1040 may be alternatively stacked above the substrate 910. A portion of the nanosheet wafer 1000 may be the first logic area (upon which the first NS structure 920A may be formed) and another portion may be the second logic area (upon which the second NS structure 920B may be formed).

FIG. 10B illustrates a stage in which the masking material may be etched to form a mask 1035 that exposes the second logic area of the wafer 1000. Then using the mask 1035, a recess may be formed in the second logic area 120, e.g., by etching, in which the upper most M nanosheets 1040 may be removed. If multiple upper most M nanosheets are removed (e.g., M≥2), then M−1 upper most dummy layers 1015 may also be removed.

FIG. 10C illustrates a stage in which a temporary spacer 1045 may be formed on boundaries—i.e., sides—of the recess. The temporary spacer 1045 may be formed above the upper most of the remaining dummy layers 1015.

FIG. 10D illustrates a stage in which a second dummy layer 1017 (e.g., with the same material as the dummy layer 1015) is grown in the recess, i.e., in the etched space of the second logic area 120.

FIG. 10E illustrates a stage in which the mask 1035 may be removed, and the second dummy layer 1017 is planarized (e.g., CMP) so that upper surfaces of the upper most nanosheet 1040, the temporary spacer 1045, and the second dummy layer 1017 are coplanar.

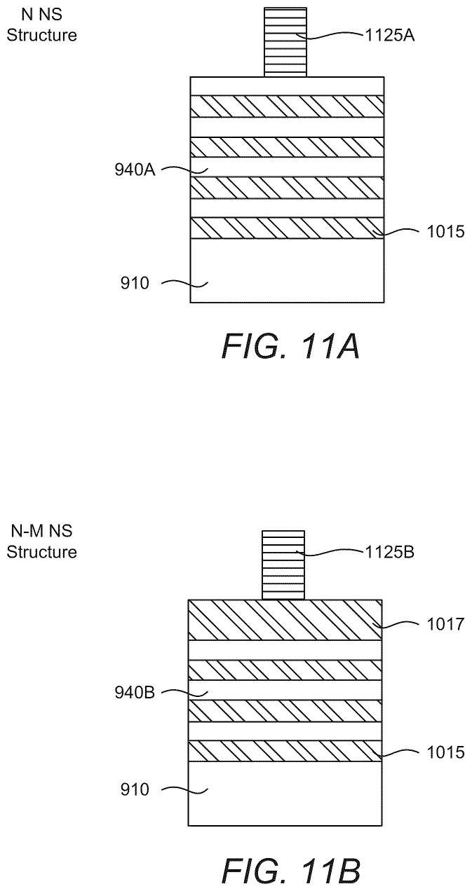

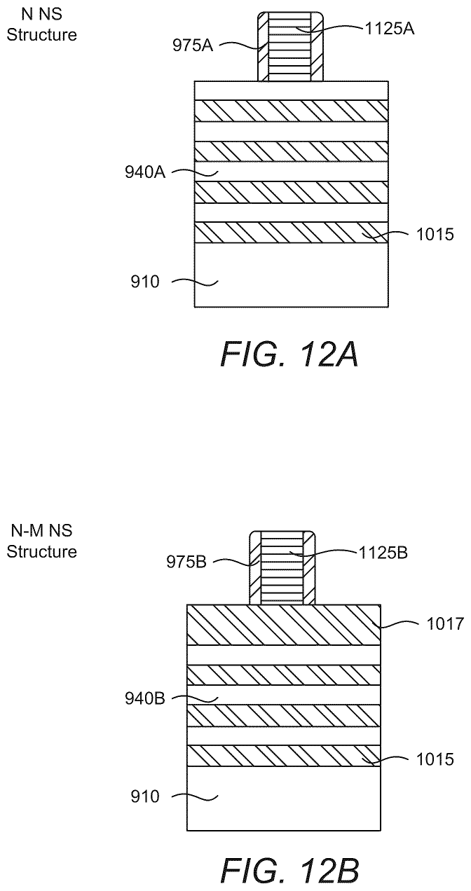

FIGS. 11A-15B generally illustrate various stages of a front end-of-line (FEOL) processes (e.g., steps e-l). As indicated, the processing stages illustrated in FIGS. 11A-15B may be referred to as “late patterning” process. FIGS. 11A, 12A, 13A, 14A and 15A illustrate stages related to the formation of the first NS structure 920A, and FIGS. 11B. 12B, 13B, 14B and 15B illustrate stages related to the formation of the second NS structure 920B. In these figures, M may be assumed to be 1. That is, the second NS structure 920B may be an N−1 NS structure. However, it will be relatively straightforward to apply the illustrated processing stages to generic N−M NS structures.

FIG. 11A illustrates a stage in which a first dummy gate 1125A may be formed on the upper most first nanosheet 940A. Note that the upper most first nanosheet 940A will also become one of the first channels. The first dummy gate 1125A may be formed using a dummy gate mask (not shown).

FIG. 11B illustrates a stage in which a second dummy gate 1125B may be formed on the upper most dummy layer, which may be the second dummy layer 1017. The second dummy gate 1125B may be also formed using the dummy gate mask used to form the first dummy gate 1125A. That is, the first and second dummy gates 1125A, 1125B may be formed concurrently. Indeed, the process steps (as illustrated in FIGS. 11A-15B) may be common to both the N and the N−M regions at each of the stages.

After forming the first dummy gate 1125A, FIG. 12A illustrates a stage in which the first upper spacers 975A may be formed. The first upper spacers 975A may be formed above the upper most first channel 940A and on the first source and drain sides of the first dummy gate 1125A.

After forming the second dummy gate 1125B, FIG. 12B illustrates a stage in which the second upper spacers 975B may be formed. The second upper spacers 975B may be formed above the second dummy layer 1017 and on the second source and drain sides of the second dummy gate 1125B. In an aspect, the first and second upper spacers 975B, 975B may be formed concurrently.

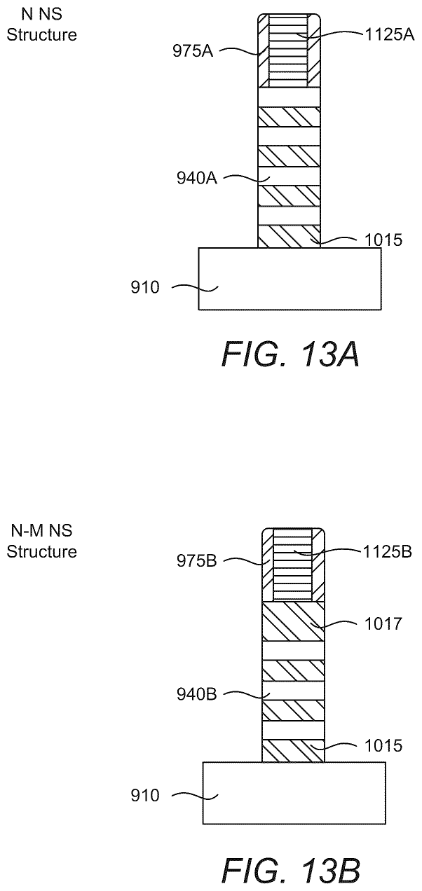

FIG. 13A illustrates a stage in which the first logic area may be etched to form recesses in the first source and drain sides. Through such etching, the substrate 910 may be exposed on both the first source and drain sides.

FIG. 13B illustrates a stage in which the second logic area may be etched to form recesses in the second source and drain sides. Through such etching, the substrate 910 may be exposed on both the second source and drain sides. In an aspect, the first and second logic areas may be etched concurrently to expose the substrate 910.

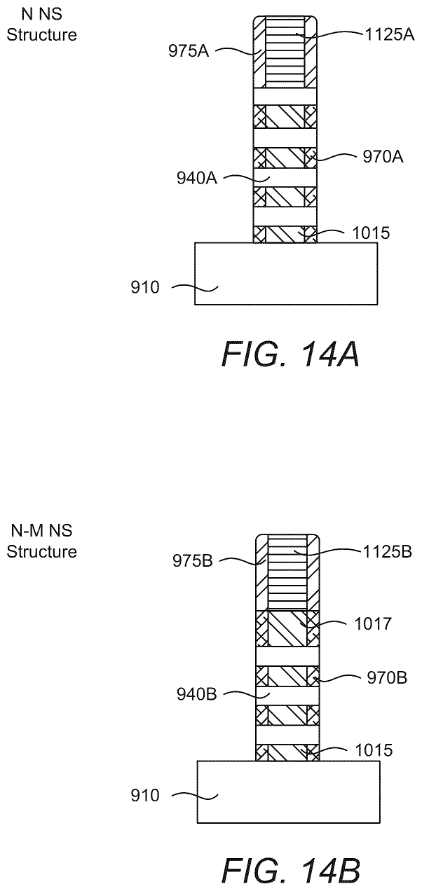

FIG. 14A illustrates a stage in which outer portions of the dummy layer 1015 in the first gate region may be removed and replaced with the first inner spacers 970A vertically below the first upper spacers 975A. The first inner spacers 970A may be alternatively stacked with the nanosheets (e.g., first nanosheets or channels 940A) in the first gate region.

FIG. 14B illustrates a stage in which outer portions of the dummy layer 1015 in the second gate region may be removed and replaced with the second inner spacers 970B vertically below the second upper spacers 975B. The second inner spacers 970B may be alternatively stacked with the nanosheets (e.g., second nanosheets or channels 940B) in the second gate region. In an aspect, the first and second inner spacers 970A, 270B may be formed concurrently.

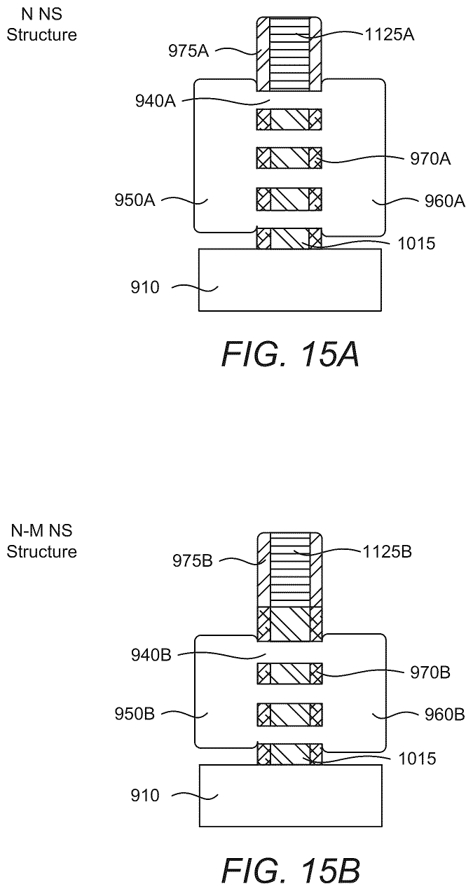

FIG. 15A illustrates a stage in which the first source and drain 250A, 260A may be formed. For example, they may be grown epitaxially. The first source and drain 250A, 260A may be formed to be coupled with (e.g., in direct contact with) the first channels 240A.

FIG. 15B illustrates a stage in which the second source and drain 250B, 260B may be formed. For example, they may be grown epitaxially. The second source and drain 950B, 960B may be formed to be coupled with (e.g., in direct contact with) the second channels 940B. In an aspect, the first and second sources 950A, 950B, and first and second drains 960A, 960B may be formed concurrently.

While not shown, thereafter, the first and second dummy gates 1125A, 1125B as well as the dummy layers 1015 in the gate region may be stripped or otherwise removed. The first gate 930A may be formed in the first gate region in place of the removed first dummy gate 1125A and the dummy layer 1015. Similarly, the second gate 930B may be formed in the second gate region in place of the removed second dummy gate 1125B and the dummy layer 1015.

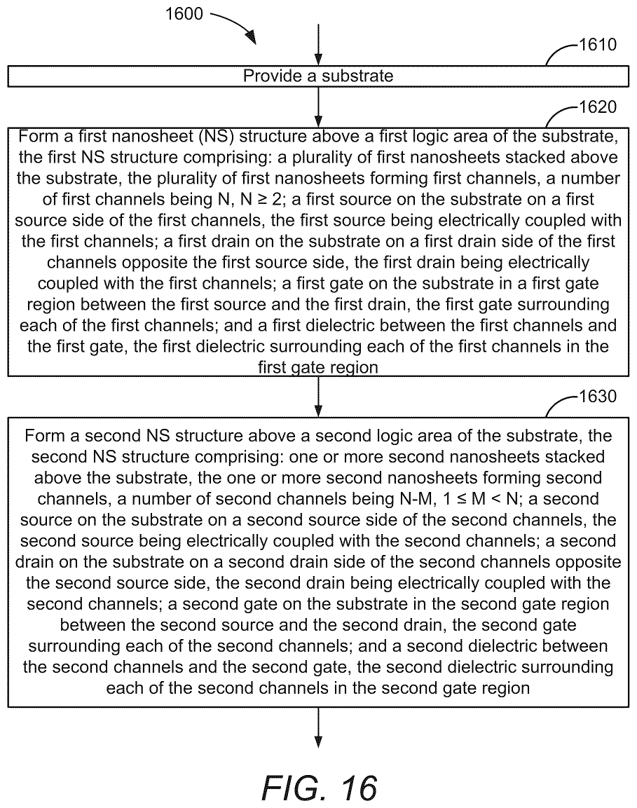

FIG. 16 illustrates a flow chart of an example method 1600 of fabricating a GAA device, such as the devices 200, 900, in accordance with one or more aspects of the disclosure. In block 1610, a substrate (e.g., substrate 210, 910) may be provided. The substrate may be a substrate of a nanosheet wafer, e.g., with first and second logic areas 110, 120.

In block 1620, a first NS structure (e.g., first NS structure 220A, 920A) may be formed. The first NS structure may be formed above a first logic area (e.g., first logic area 110) of the substrate. The details of the first NS structure are discussed above.

In block 1630, a second NS structure (e.g., second NS structure 220B, 920B) may be formed. The second NS structure may be formed above a second logic area (e.g., second logic area 120) of the substrate. The details of the second NS structure are discussed above.

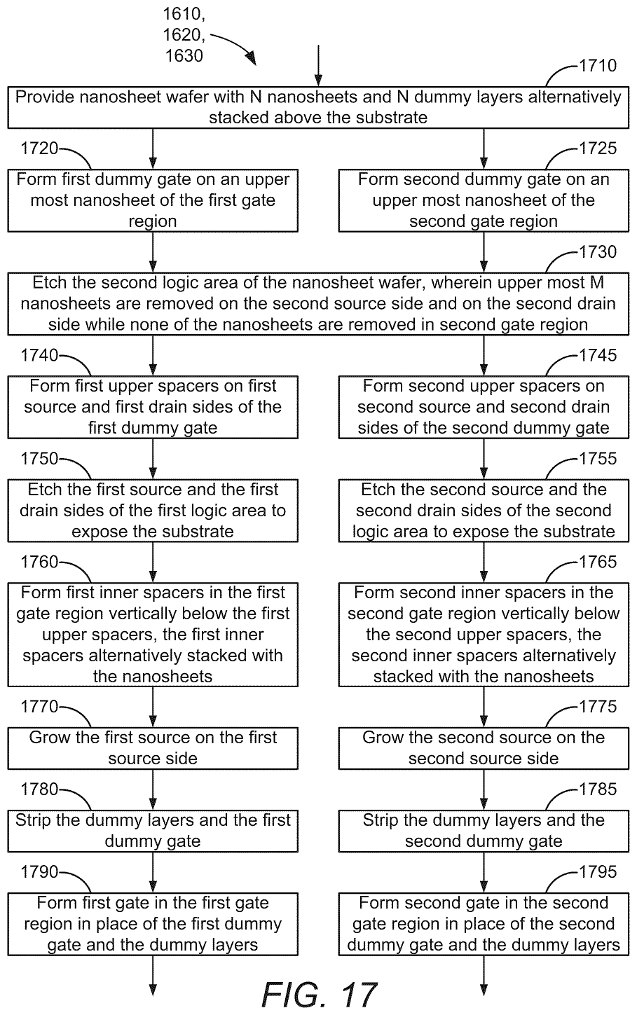

FIG. 17 illustrates a flow chart of an example process to implement blocks 1610, 1620, 1630 of FIG. 16. In this instance, FIG. 17 may be a flow chart of an example method to fabricate the GAA device 200, i.e., the first embodiment of the GAA device. In other words, the flow chart of FIG. 17 may be an example of a late patterning process.

In block 1710, a nanosheet wafer (e.g., nanosheet wafer 300) may be provided. The nanosheet wafer may include N nanosheets (e.g., nanosheets 340) and N dummy layers (e.g., dummy layers 315) alternatively stacked above the substrate (210).

In block 1720, a first dummy gate (e.g., first dummy gate 425A) may be formed on an upper most nanosheet of the first gate region. In block 1725, a second dummy gate (e.g., second dummy gate 425B) may be formed on an upper most nanosheet of the second gate region. Blocks 1720 and 1725 may be performed concurrently.

In block 1730, the second logic area (e.g., second area 120) of the nanosheet wafer may be etched. As a result, upper most M nanosheets may be removed on the second source side and on the second drain side while none of the nanosheets are removed in second gate region. If M≥2, then upper most M−1 dummy layers may also be removed on the second source and drain sides.

In block 1740, the first upper spacers (e.g., first upper spacers 275A) may be formed on the first source and the first drain sides of the first dummy gate. In block 1745, the second upper spacers (e.g., second upper spacers 275B) may be formed on the second source and the second drain sides of the second dummy gate. Blocks 1740 and 1745 may be performed concurrently.

In block 1750, the first source and the first drain sides of the first logic area (e.g., first logic area 110) may be etched to expose the substrate. In block 1755, the second source and the second drain sides of the second logic area may be etched to expose the substrate. Blocks 1750 and 1755 may be performed concurrently.

In block 1760, the first inner spacers (e.g., first inner spacers 270A) may be formed in the first gate region vertically below the first upper spacers. The first inner spacers alternatively stacked with the nanosheets in the first gate region. In block 1765, the second inner spacers (e.g., second inner spacers 270B) may be formed in the second gate region vertically below the second upper spacers. The second inner spacers alternatively stacked with the nanosheets in the second gate region. Blocks 1760 and 1765 may be performed concurrently.

In block 1770, the first source (e.g., the first source 250A) may be grown on the first source side in the first gate region. In block 1775, the second source (e.g., the second source 250B) may be grown on the second source side in the second gate region. Blocks 1770 and 1775 may be performed concurrently.

In block 1780, the dummy layers and the first dummy gate in the first gate region may be stripped or otherwise removed. In block 1785, the dummy layers and the second dummy gate in the second gate region may be stripped or otherwise removed. Blocks 1780 and 1785 may be performed concurrently.

In block 1790, the first gate (e.g., the first gate 230A) may be formed in the first gate region in place of the first dummy gate and the dummy layers. In block 1795, the second gate (e.g., the second gate 230B) may be formed in the second gate region in place of the second dummy gate and the dummy layers. Blocks 1780 and 1785 may be performed concurrently.

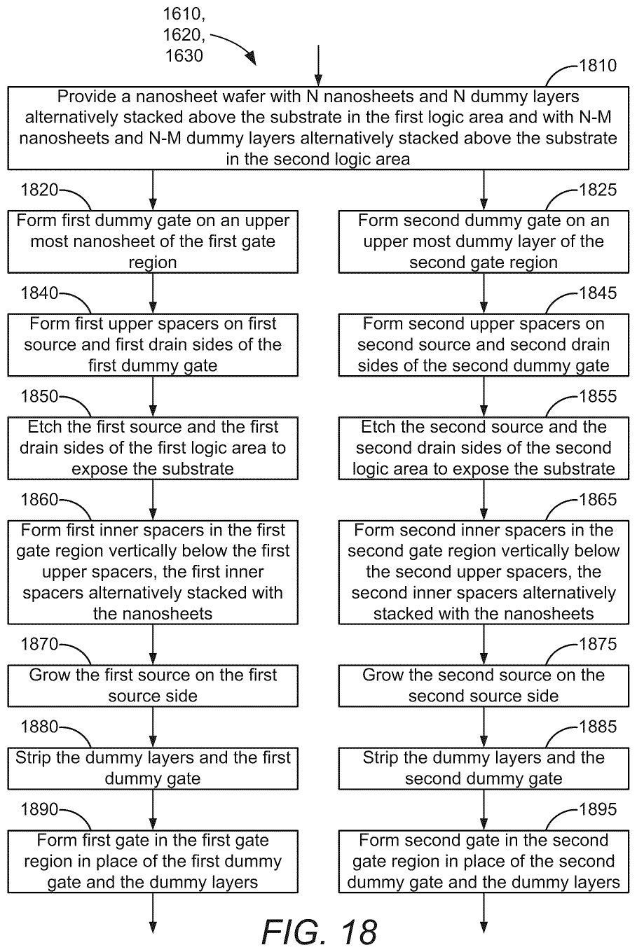

FIG. 18 illustrates a flow chart of an example process to implement blocks 1610, 1620, 1630 of FIG. 16. In this instance, FIG. 18 may be a flow chart of an example method to fabricate the GAA device 900, i.e., the second embodiment of the GAA device. In other words, the flow chart of FIG. 18 may be an example of an early patterning process.

In block 1810, a nanosheet wafer (e.g., nanosheet wafer 1000) may be provided. The nanosheet wafer may include N nanosheets (e.g., nanosheets 1040) and N dummy layers (e.g., dummy layers 1015) alternatively stacked above the substrate (e.g., substrate 910) in the first logic area (e.g., first logic area 110). The nanosheet wafer may also include N−M nanosheets and N−M+1 dummy layers alternatively stacked above the substrate in the second logic area (e.g., second logic area 120).

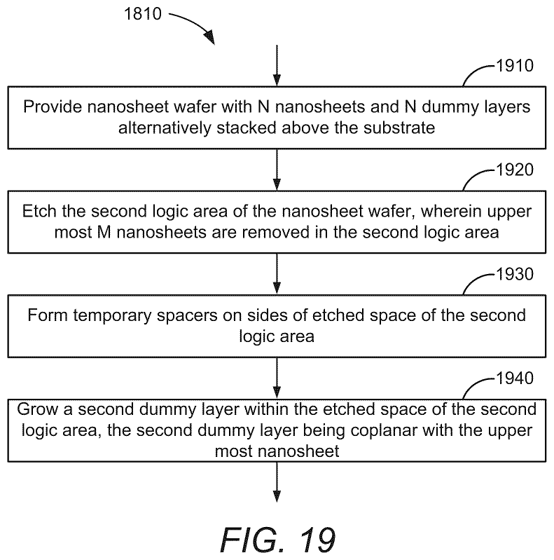

FIG. 19 illustrates a flow chart of an example process to implement block 1810. In block 1910, the nanosheet wafer with N nanosheets and N dummy layers alternatively stacked above the substrate may be provided.

In block 1920, the second logic area of the nanosheet wafer may be etched. As a result, upper most M nanosheets may be removed in the second logic area.

In block 1930, temporary spacers (e.g., temporary spacers 1045) may be formed on sides of etched space of the second logic area.

In block 1940, a second dummy layer (e.g., second dummy layer 1017) may be grown within the etched space of the second logic area. The second dummy layer may be coplanar with the upper most nanosheet.

Referring back to FIG. 18, in block 1820, a first dummy gate (e.g., first dummy gate 1125A) may be formed on an upper most nanosheet of the first gate region. In block 1825, a second dummy gate (e.g., second dummy gate 1125B) may be formed on an upper most dummy layer of the second gate region, which may be the second dummy layer. Blocks 1820 and 1825 may be performed concurrently.

In block 1840, the first upper spacers (e.g., first upper spacers 975A) may be formed on the first source and the first drain sides of the first dummy gate. In block 1845, the second upper spacers (e.g., second upper spacers 975B) may be formed on the second source and the second drain sides of the second dummy gate. Blocks 1840 and 1845 may be performed concurrently.

In block 1850, the first source and the first drain sides of the first logic area may be etched to expose the substrate. In block 1855, the second source and the second drain sides of the second logic area may be etched to expose the substrate. Blocks 1850 and 1785 may be performed concurrently.

In block 1860, the first inner spacers (e.g., first inner spacers 970A) may be formed in the first gate region vertically below the first upper spacers. The first inner spacers alternatively stacked with the nanosheets in the first gate region. In block 1865, the second inner spacers (e.g., second inner spacers 970B) may be formed in the second gate region vertically below the second upper spacers. The second inner spacers alternatively stacked with the nanosheets in the second gate region. Blocks 1860 and 1865 may be performed concurrently.

In block 1870, the first source (e.g., the first source 950A) may be grown on the first source side in the first gate region. In block 1875, the second source (e.g., the second source 950B) may be grown on the second source side in the second gate region. Blocks 1870 and 1875 may be performed concurrently.

In block 1880, the dummy layers and the first dummy gate in the first gate region may be stripped or otherwise removed. In block 1885, the dummy layers and the second dummy gate in the second gate region may be stripped or otherwise removed. Blocks 1880 and 1885 may be performed concurrently.

In block 1890, the first gate (e.g., the first gate 930A) may be formed in the first gate region in place of the first dummy gate and the dummy layers. In block 1895, the second gate (e.g., the second gate 930B) may be formed in the second gate region in place of the second dummy gate and the dummy layers. Blocks 1880 and 1885 may be performed concurrently.

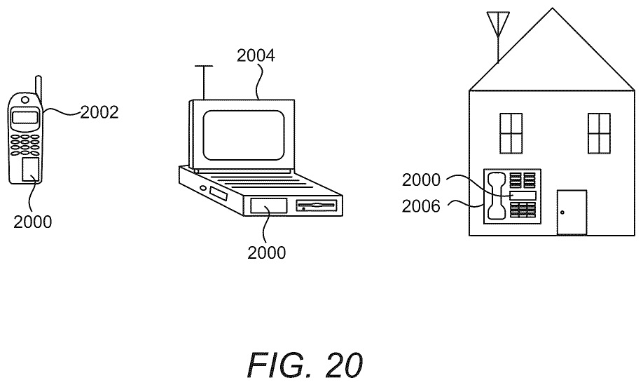

FIG. 20 illustrates various electronic devices 2000 that may be integrated with any of the aforementioned GAA devices in accordance with various aspects of the disclosure. For example, a mobile phone device 2002, a laptop computer device 2004, and a fixed location terminal device 2006 may each be considered generally user equipment (UE) and may include one or more devices (e.g., devices 200, 900) as described herein. The devices 2002, 2004, 2006 illustrated in FIG. 20 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A gate-all-around (GAA) device, comprising: a substrate; a first nanosheet (NS) structure formed above a first logic area of the substrate; and a second nanosheet (NS) structure formed above a second logic area of the substrate different from the first logic area, wherein the first NS structure comprises: a plurality of first nanosheets stacked above the substrate, the plurality of first nanosheets forming first channels, a number of first channels being N. N≥2; a first source on the substrate on a first source side of the first channels, the first source being electrically coupled with the first channels; a first drain on the substrate on a first drain side of the first channels opposite the first source side, the first drain being electrically coupled with the first channels; a first gate on the substrate in a first gate region between the first source and the first drain, the first gate surrounding each of the first channels; and a first dielectric between the first channels and the first gate, the first dielectric surrounding each of the first channels in the first gate region, wherein the second NS structure comprises: one or more second nanosheets stacked above the substrate, the one or more second nanosheets forming second channels, a number of second channels being N−M, 1≤M<N; a second source on the substrate on a second source side of the second channels, the second source being electrically coupled with the second channels; a second drain on the substrate on a second drain side of the second channels opposite the second source side, the second drain being electrically coupled with the second channels; a second gate on the substrate in a second gate region between the second source and the second drain, the second gate surrounding each of the second channels; and a second dielectric between the second channels and the second gate, the second dielectric surrounding each of the second channels in the second gate region, and wherein a number of first nanosheets is N, and a number of second nanosheets is N, a lower most N−M second nanosheets forming the second channels.

Clause 2: The GAA device of clause 1, wherein an upper surface of the first gate and an upper surface of the second gate are coplanar.

Clause 3: The GAA device of any of clauses 1-2, wherein the first NS structure further comprises first inner spacers formed between the first source and the first gate and formed between the first drain and the first gate, and the second NS structure further comprises second inner spacers formed between the second source and the second gate and formed between the second drain and the second gate.

Clause 4: The GAA device of clause 3, wherein the first NS structure further comprises first upper spacers formed above an upper most first channel and formed on the first source and drain sides of the first gate, and the second NS structure further comprises second upper spacers formed above an upper most second channel and formed on the second source and drain sides of the second gate.

Clause 5: The GAA device of clause 4, wherein a dielectric constant of the first inner spacers is different from a dielectric constant of the first upper spacers, or a dielectric constant of the second inner spacers is different from a dielectric constant of the second upper spacers, or both.

Clause 6: The GAA device of any of clauses 4-5, wherein an upper surface of the first gate and upper surfaces of the first upper spacers are at a same first height, or an upper surface of the second gate and upper surfaces of the second upper spacers are at a same second height, or both.

Clause 7: The GAA device of any of clauses 1-6, wherein upper most M second nanosheets are floating.

Clause 8: The GAA device of clause 7, wherein second upper spacers are formed on the second source and drain sides of the upper most M second nanosheets, and the second upper spacers are formed above and in direct contact with upper most second inner spacers.

Clause 9: The GAA device of any of clauses 1-8, wherein the GAA device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 10: A gate-all-around (GAA) device, comprising: a substrate; a first nanosheet (NS) structure formed above a first logic area of the substrate; and a second nanosheet (NS) structure formed above a second logic area of the substrate different from the first logic area, wherein the first NS structure comprises: a plurality of first nanosheets stacked above the substrate, the plurality of first nanosheets forming first channels, a number of first channels being N. N≥2; a first source on the substrate on a first source side of the first channels, the first source being electrically coupled with the first channels; a first drain on the substrate on a first drain side of the first channels opposite the first source side, the first drain being electrically coupled with the first channels; a first gate on the substrate in a first gate region between the first source and the first drain, the first gate surrounding each of the first channels; and a first dielectric between the first channels and the first gate, the first dielectric surrounding each of the first channels in the first gate region, wherein the second NS structure comprises: one or more second nanosheets stacked above the substrate, the one or more second nanosheets forming second channels, a number of second channels being N−M, 1≤M<N; a second source on the substrate on a second source side of the second channels, the second source being electrically coupled with the second channels; a second drain on the substrate on a second drain side of the second channels opposite the second source side, the second drain being electrically coupled with the second channels; a second gate on the substrate in a second gate region between the second source and the second drain, the second gate surrounding each of the second channels; a second dielectric between the second channels and the second gate, the second dielectric surrounding each of the second channels in the second gate region; second inner spacers formed between the second source and the second gate and formed between the second drain and the second gate; and second upper spacers formed above an upper most second channel and formed on the second source and drain sides of the second gate, a dielectric constant of the second inner spacers being different from a dielectric constant of the second upper spacers, and wherein a portion of the second inner spacers is formed above the upper most second channel.

Clause 11: The GAA device of clause 10, wherein an upper surface of the first gate and an upper surface of the second gate are coplanar.

Clause 12: The GAA device of any of clauses 10-11, wherein the first NS structure further comprises: first inner spacers formed between the first source and the first gate and formed between the first drain and the first gate; and first upper spacers formed above an upper most first channel and formed on the first source and drain sides of the first gate.

Clause 13: The GAA device of clause 12, wherein a dielectric constant of the first inner spacers is different from a dielectric constant of the first upper spacers.

Clause 14: The GAA device of any of clauses 12-13, wherein an upper surface of the first gate and upper surfaces of the first upper spacers are at a same first height, or an upper surface of the second gate and upper surfaces of the second upper spacers are at a same second height, or both.

Clause 15: The GAA device of any of clauses 10-14, wherein a number of first nanosheets is N, and a number of second nanosheets is N−M.

Clause 16: The GAA device of any of clauses 10-15, wherein the second upper spacers are formed on the second source and drain sides of the second gate above the upper most second nanosheet, and the second upper spacers are formed above and in direct contact with upper most second inner spacers.

Clause 17: The GAA device of any of clauses 10-16, wherein the GAA device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 18: A method of fabricating a gate-all-around (GAA) device, the method comprising: providing a substrate; forming a first nanosheet (NS) structure above a first logic area of the substrate; and forming a second nanosheet (NS) structure above a second logic area of the substrate different from the first logic area, wherein the first NS structure comprises: a plurality of first nanosheets stacked above the substrate, the plurality of first nanosheets forming first channels, a number of first channels being N, N≥2; a first source on the substrate on a first source side of the first channels, the first source being electrically coupled with the first channels; a first drain on the substrate on a first drain side of the first channels opposite the first source side, the first drain being electrically coupled with the first channels; a first gate on the substrate in a first gate region between the first source and the first drain, the first gate surrounding each of the first channels; and a first dielectric between the first channels and the first gate, the first dielectric surrounding each of the first channels in the first gate region, wherein the second NS structure comprises: one or more second nanosheets stacked above the substrate, the one or more second nanosheets forming second channels, a number of second channels being N−M. 1≤M<N; a second source on the substrate on a second source side of the second channels, the second source being electrically coupled with the second channels; a second drain on the substrate on a second drain side of the second channels opposite the second source side, the second drain being electrically coupled with the second channels; a second gate on the substrate in a second gate region between the second source and the second drain, the second gate surrounding each of the second channels; and a second dielectric between the second channels and the second gate, the second dielectric surrounding each of the second channels in the second gate region, and wherein a number of first nanosheets is N, and a number of second nanosheets is N, a lower most N−M second nanosheets forming the second channels.

Clause 19: The method of clause 18, wherein the first NS structure further comprises first inner spacers formed between the first source and the first gate and formed between the first drain and the first gate, and the second NS structure further comprises second inner spacers formed between the second source and the second gate and formed between the second drain and the second gate.

Clause 20: The method of clause 19, wherein the first NS structure further comprises first upper spacers formed above an upper most first channel and formed on the first source and drain sides of the first gate, and the second NS structure further comprises second upper spacers formed above an upper most second channel and formed on the second source and drain sides of the second gate.

Clause 21: The method of clause 20, wherein a dielectric constant of the first inner spacers is different from a dielectric constant of the first upper spacers, or a dielectric constant of the second inner spacers is different from a dielectric constant of the second upper spacers, or both.

Clause 22: The method of any of clauses 20-21, wherein an upper surface of the first gate and upper surfaces of the first upper spacers are at a same first height, or an upper surface of the second gate and upper surfaces of the second upper spacers are at a same second height, or both.

Clause 23: The method of any of clauses 18-22, wherein upper most M second nanosheets are floating.

Clause 24: The method of any of clauses 18-23, wherein providing the substrate, forming the first NS structure, and forming the second NS structure comprise: providing a nanosheet wafer with N nanosheets and N dummy layers alternatively stacked above the substrate; forming a first dummy gate on an upper most nanosheet of the first gate region; forming a second dummy gate on an upper most nanosheet of the second gate region; etching the second logic area of the nanosheet wafer, wherein upper most M nanosheets are removed on the second source side and on the second drain side while none of the nanosheets are removed in second gate region; forming first upper spacers on the first source and the first drain sides of the first dummy gate; forming second upper spacers on the second source and the second drain sides of the second dummy gate; etching the first source and the first drain sides of the first logic area to expose the substrate; etching the second source and the second drain sides of the second logic area to expose the substrate; forming first inner spacers in the first gate region vertically below the first upper spacers, the first inner spacers alternatively stacked with the nanosheets in the first gate region; forming second inner spacers in the second gate region vertically below the second upper spacers, the second inner spacers alternatively stacked with the nanosheets in the second gate region; growing the first source on the first source side in the first gate region; growing the second source on the second source side in the second gate region; stripping the dummy layers and the first dummy gate in the first gate region; stripping the dummy layers and the second dummy gate in the second gate region; forming the first gate in the first gate region in place of the first dummy gate and the dummy layers; and forming the second gate in the second gate region in place of the second dummy gate and the dummy layers.

Clause 25: A method of fabricating a gate-all-around (GAA) device, the method comprising: providing a substrate; forming a first nanosheet (NS) structure above a first logic area of the substrate; and forming a second nanosheet (NS) structure above a second logic area of the substrate different from the first logic area, wherein the first NS structure comprises: a plurality of first nanosheets stacked above the substrate, the plurality of first nanosheets forming first channels, a number of first channels being N, N≥2; a first source on the substrate on a first source side of the first channels, the first source being electrically coupled with the first channels; a first drain on the substrate on a first drain side of the first channels opposite the first source side, the first drain being electrically coupled with the first channels; a first gate on the substrate in a first gate region between the first source and the first drain, the first gate surrounding each of the first channels; and a first dielectric between the first channels and the first gate, the first dielectric surrounding each of the first channels in the first gate region, wherein the second NS structure comprises: one or more second nanosheets stacked above the substrate, the one or more second nanosheets forming second channels, a number of second channels being N−M. 1≤M<N; a second source on the substrate on a second source side of the second channels, the second source being electrically coupled with the second channels; a second drain on the substrate on a second drain side of the second channels opposite the second source side, the second drain being electrically coupled with the second channels; a second gate on the substrate in a second gate region between the second source and the second drain, the second gate surrounding each of the second channels; a second dielectric between the second channels and the second gate, the second dielectric surrounding each of the second channels in the second gate region; second inner spacers formed between the second source and the second gate and formed between the second drain and the second gate; and second upper spacers formed above an upper most second channel and formed on the second source and drain sides of the second gate, a dielectric constant of the second inner spacers being different from a dielectric constant of the second upper spacers, and wherein a portion of the second inner spacers is formed above the upper most second channel.

Clause 26: The method of clause 25, wherein the first NS structure further comprises: first inner spacers formed between the first source and the first gate and formed between the first drain and the first gate; and first upper spacers formed above an upper most first channel and formed on the first source and drain sides of the first gate.

Clause 27: The method of clause 26, wherein a dielectric constant of the first inner spacers is different from a dielectric constant of the first upper spacers.

Clause 28: The method of any of clauses 26-27, an upper surface of the first gate and upper surfaces of the first upper spacers are at a same first height, or an upper surface of the second gate and upper surfaces of the second upper spacers are at a same second height, or both.

Clause 29: The method of any of clauses 25-28, wherein providing the substrate, forming the first NS structure, and forming the second NS structure comprise: providing a nanosheet wafer with N nanosheets and N dummy layers alternatively stacked above the substrate in the first logic area and with N−M nanosheets and N−M+1 dummy layers alternatively stacked above the substrate in the second logic area; forming a first dummy gate on an upper most nanosheet of the first gate region; forming a second dummy gate on an upper most dummy layer of the second gate region; forming first upper spacers on the first source and the first drain sides of the first dummy gate; forming the second upper spacers on the second source and the second drain sides of the second dummy gate; etching the first source and the first drain sides of the first logic area to expose the substrate; etching the second source and the second drain sides of the second logic area to expose the substrate; forming first inner spacers in the first gate region vertically below the first upper spacers, the first inner spacers alternatively stacked with the nanosheets in the first gate region; forming the second inner spacers in the second gate region vertically below the second upper spacers, the second inner spacers alternatively stacked with the nanosheets in the second gate region; growing the first source on the first source side in the first gate region; growing the second source on the second source side in the second gate region; stripping the dummy layers and the first dummy gate in the first gate region; stripping the dummy layers and the second dummy gate in the second gate region; forming the first gate in the first gate region in place of the first dummy gate and the dummy layers; and forming the second gate in the second gate region in place of the second dummy gate and the dummy layers.

Clause 30: The method of clause 29, wherein providing the nanosheet wafer with N nanosheets and N dummy layers alternatively stacked above the substrate in the first logic area and with N−M nanosheets and N−M+1 dummy layers alternatively stacked above the substrate in the second logic area comprises: providing the nanosheet wafer with N nanosheets and N dummy layers alternatively stacked above the substrate; etching the second logic area of the nanosheet wafer, wherein upper most M nanosheets are removed in the second logic area; forming temporary spacers on sides of etched space of the second logic area; and growing a dummy layer within the etched space of the second logic area, the dummy layer being coplanar with upper most nanosheet.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A gate-all-around (GAA) device, comprising:
a substrate;
a first nanosheet (NS) structure formed above a first logic area of the substrate; and
a second nanosheet (NS) structure formed above a second logic area of the substrate different from the first logic area,
wherein the first NS structure comprises:
a plurality of first nanosheets stacked above the substrate, the plurality of first nanosheets forming first channels, a number of first channels being N, N≥2;
a first source on the substrate on a first source side of the first channels, the first source being electrically coupled with the first channels;
a first drain on the substrate on a first drain side of the first channels opposite the first source side, the first drain being electrically coupled with the first channels;
a first gate on the substrate in a first gate region between the first source and the first drain, the first gate surrounding each of the first channels; and
a first dielectric between the first channels and the first gate, the first dielectric surrounding each of the first channels in the first gate region,
wherein the second NS structure comprises:
one or more second nanosheets stacked above the substrate, the one or more second nanosheets forming second channels, a number of second channels being N−M, 1≤M<N;
a second source on the substrate on a second source side of the second channels, the second source being electrically coupled with the second channels;
a second drain on the substrate on a second drain side of the second channels opposite the second source side, the second drain being electrically coupled with the second channels;
a second gate on the substrate in a second gate region between the second source and the second drain, the second gate surrounding each of the second channels; and
a second dielectric between the second channels and the second gate, the second dielectric surrounding each of the second channels in the second gate region, and
wherein a number of first nanosheets is N, and a number of second nanosheets is N, a lower most N−M second nanosheets forming the second channels.

2. The GAA device of claim 1, wherein an upper surface of the first gate and an upper surface of the second gate are coplanar.

3. The GAA device of claim 1, wherein
the first NS structure further comprises first inner spacers formed between the first source and the first gate and formed between the first drain and the first gate, and
the second NS structure further comprises second inner spacers formed between the second source and the second gate and formed between the second drain and the second gate.

4. The GAA device of claim 3, wherein
the first NS structure further comprises first upper spacers formed above an upper most first channel and formed on the first source and drain sides of the first gate, and
the second NS structure further comprises second upper spacers formed above an upper most second channel and formed on the second source and drain sides of the second gate.

5. The GAA device of claim 4, wherein
a dielectric constant of the first inner spacers is different from a dielectric constant of the first upper spacers, or
a dielectric constant of the second inner spacers is different from a dielectric constant of the second upper spacers, or
both.

6. The GAA device of claim 4, wherein
an upper surface of the first gate and upper surfaces of the first upper spacers are at a same first height, or
an upper surface of the second gate and upper surfaces of the second upper spacers are at a same second height, or
both.

7. The GAA device of claim 1, wherein upper most M second nanosheets are floating.

8. The GAA device of claim 7, wherein
second upper spacers are formed on the second source and drain sides of the upper most M second nanosheets, and
the second upper spacers are formed above and in direct contact with upper most second inner spacers.

9. The GAA device of claim 1, wherein the GAA device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

10. A gate-all-around (GAA) device, comprising:
a substrate;
a first nanosheet (NS) structure formed above a first logic area of the substrate; and
a second nanosheet (NS) structure formed above a second logic area of the substrate different from the first logic area,
wherein the first NS structure comprises:
a plurality of first nanosheets stacked above the substrate, the plurality of first nanosheets forming first channels, a number of first channels being N, N≥2;
a first source on the substrate on a first source side of the first channels, the first source being electrically coupled with the first channels;
a first drain on the substrate on a first drain side of the first channels opposite the first source side, the first drain being electrically coupled with the first channels;
a first gate on the substrate in a first gate region between the first source and the first drain, the first gate surrounding each of the first channels; and
a first dielectric between the first channels and the first gate, the first dielectric surrounding each of the first channels in the first gate region,
wherein the second NS structure comprises:
one or more second nanosheets stacked above the substrate, the one or more second nanosheets forming second channels, a number of second channels being N−M, 1≤M<N;
a second source on the substrate on a second source side of the second channels, the second source being electrically coupled with the second channels;
a second drain on the substrate on a second drain side of the second channels opposite the second source side, the second drain being electrically coupled with the second channels;
a second gate on the substrate in a second gate region between the second source and the second drain, the second gate surrounding each of the second channels;
a second dielectric between the second channels and the second gate, the second dielectric surrounding each of the second channels in the second gate region;
second inner spacers formed between the second source and the second gate and formed between the second drain and the second gate; and
second upper spacers formed above an upper most second channel and formed on the second source and drain sides of the second gate, a dielectric constant of the second inner spacers being different from a dielectric constant of the second upper spacers, and
wherein a portion of the second inner spacers is formed above the upper most second channel.

11. The GAA device of claim 10, wherein an upper surface of the first gate and an upper surface of the second gate are coplanar.

12. The GAA device of claim 10, wherein the first NS structure further comprises:
first inner spacers formed between the first source and the first gate and formed between the first drain and the first gate; and
first upper spacers formed above an upper most first channel and formed on the first source and drain sides of the first gate.

13. The GAA device of claim 12, wherein a dielectric constant of the first inner spacers is different from a dielectric constant of the first upper spacers.

14. The GAA device of claim 12, wherein
an upper surface of the first gate and upper surfaces of the first upper spacers are at a same first height, or
an upper surface of the second gate and upper surfaces of the second upper spacers are at a same second height, or
both.

15. The GAA device of claim 10, wherein
a number of first nanosheets is N, and
a number of second nanosheets is N−M.

16. The GAA device of claim 10, wherein
the second upper spacers are formed on the second source and drain sides of the second gate above the upper most second nanosheet, and
the second upper spacers are formed above and in direct contact with upper most second inner spacers.

17. The GAA device of claim 10, wherein the GAA device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

18. A method of fabricating a gate-all-around (GAA) device, comprising:
providing a substrate;
forming a first nanosheet (NS) structure above a first logic area of the substrate; and
forming a second nanosheet (NS) structure above a second logic area of the substrate different from the first logic area,
wherein the first NS structure comprises:
a plurality of first nanosheets stacked above the substrate, the plurality of first nanosheets forming first channels, a number of first channels being N, N≥2;
a first source on the substrate on a first source side of the first channels, the first source being electrically coupled with the first channels;
a first drain on the substrate on a first drain side of the first channels opposite the first source side, the first drain being electrically coupled with the first channels;
a first gate on the substrate in a first gate region between the first source and the first drain, the first gate surrounding each of the first channels; and
a first dielectric between the first channels and the first gate, the first dielectric surrounding each of the first channels in the first gate region, wherein the second NS structure comprises:
one or more second nanosheets stacked above the substrate, the one or more second nanosheets forming second channels, a number of second channels being N−M, 1≤M<N;
a second source on the substrate on a second source side of the second channels, the second source being electrically coupled with the second channels;
a second drain on the substrate on a second drain side of the second channels opposite the second source side, the second drain being electrically coupled with the second channels;
a second gate on the substrate in a second gate region between the second source and the second drain, the second gate surrounding each of the second channels; and
a second dielectric between the second channels and the second gate, the second dielectric surrounding each of the second channels in the second gate region, and
wherein a number of first nanosheets is N, and a number of second nanosheets is N, a lower most N−M second nanosheets forming the second channels.

19. The method of claim 18, wherein
the first NS structure further comprises first inner spacers formed between the first source and the first gate and formed between the first drain and the first gate, and
the second NS structure further comprises second inner spacers formed between the second source and the second gate and formed between the second drain and the second gate.

20. The method of claim 19, wherein
the first NS structure further comprises first upper spacers formed above an upper most first channel and formed on the first source and drain sides of the first gate, and
the second NS structure further comprises second upper spacers formed above an upper most second channel and formed on the second source and drain sides of the second gate.

21. The method of claim 20, wherein
a dielectric constant of the first inner spacers is different from a dielectric constant of the first upper spacers, or
a dielectric constant of the second inner spacers is different from a dielectric constant of the second upper spacers, or
both.

22. The method of claim 20, wherein
an upper surface of the first gate and upper surfaces of the first upper spacers are at a same first height, or
an upper surface of the second gate and upper surfaces of the second upper spacers are at a same second height, or
both.

23. The method of claim 18, wherein upper most M second nanosheets are floating.

24. The method of claim 18, wherein providing the substrate, forming the first NS structure, and forming the second NS structure comprise:
providing a nanosheet wafer with N nanosheets and N dummy layers alternatively stacked above the substrate;
forming a first dummy gate on an upper most nanosheet of the first gate region;
forming a second dummy gate on an upper most nanosheet of the second gate region;
etching the second logic area of the nanosheet wafer, wherein upper most M nanosheets are removed on the second source side and on the second drain side while none of the nanosheets are removed in second gate region;
forming first upper spacers on the first source and the first drain sides of the first dummy gate;
forming second upper spacers on the second source and the second drain sides of the second dummy gate;
etching the first source and the first drain sides of the first logic area to expose the substrate;
etching the second source and the second drain sides of the second logic area to expose the substrate;
forming first inner spacers in the first gate region vertically below the first upper spacers, the first inner spacers alternatively stacked with the nanosheets in the first gate region;
forming second inner spacers in the second gate region vertically below the second upper spacers, the second inner spacers alternatively stacked with the nanosheets in the second gate region;
growing the first source on the first source side in the first gate region;
growing the second source on the second source side in the second gate region;
stripping the dummy layers and the first dummy gate in the first gate region;
stripping the dummy layers and the second dummy gate in the second gate region;
forming the first gate in the first gate region in place of the first dummy gate and the dummy layers; and
forming the second gate in the second gate region in place of the second dummy gate and the dummy layers.

25. A method of fabricating a gate-all-around (GAA) device, comprising:
providing a substrate;
forming a first nanosheet (NS) structure above a first logic area of the substrate; and
forming a second nanosheet (NS) structure above a second logic area of the substrate different from the first logic area,
wherein the first NS structure comprises:
a plurality of first nanosheets stacked above the substrate, the plurality of first nanosheets forming first channels, a number of first channels being N, N≥2;
a first source on the substrate on a first source side of the first channels, the first source being electrically coupled with the first channels;
a first drain on the substrate on a first drain side of the first channels opposite the first source side, the first drain being electrically coupled with the first channels;
a first gate on the substrate in a first gate region between the first source and the first drain, the first gate surrounding each of the first channels; and
a first dielectric between the first channels and the first gate, the first dielectric surrounding each of the first channels in the first gate region,
wherein the second NS structure comprises:
one or more second nanosheets stacked above the substrate, the one or more second nanosheets forming second channels, a number of second channels being N−M, 1≤M<N;
a second source on the substrate on a second source side of the second channels, the second source being electrically coupled with the second channels;
a second drain on the substrate on a second drain side of the second channels opposite the second source side, the second drain being electrically coupled with the second channels;
a second gate on the substrate in a second gate region between the second source and the second drain, the second gate surrounding each of the second channels;
a second dielectric between the second channels and the second gate, the second dielectric surrounding each of the second channels in the second gate region;
second inner spacers formed between the second source and the second gate and formed between the second drain and the second gate; and
second upper spacers formed above an upper most second channel and formed on the second source and drain sides of the second gate, a dielectric constant of the second inner spacers being different from a dielectric constant of the second upper spacers, and
wherein a portion of the second inner spacers is formed above the upper most second channel.

26. The method of claim 25, wherein the first NS structure further comprises:
first inner spacers formed between the first source and the first gate and formed between the first drain and the first gate; and
first upper spacers formed above an upper most first channel and formed on the first source and drain sides of the first gate.

27. The method of claim 26, wherein a dielectric constant of the first inner spacers is different from a dielectric constant of the first upper spacers.

28. The method of claim 26, wherein
an upper surface of the first gate and upper surfaces of the first upper spacers are at a same first height, or
an upper surface of the second gate and upper surfaces of the second upper spacers are at a same second height, or
both.

29. The method of claim 25, wherein providing the substrate, forming the first NS structure, and forming the second NS structure comprise:
providing a nanosheet wafer with N nanosheets and N dummy layers alternatively stacked above the substrate in the first logic area and with N−M nanosheets and N−M+1 dummy layers alternatively stacked above the substrate in the second logic area;
forming a first dummy gate on an upper most nanosheet of the first gate region;
forming a second dummy gate on an upper most dummy layer of the second gate region;
forming first upper spacers on the first source and the first drain sides of the first dummy gate;
forming the second upper spacers on the second source and the second drain sides of the second dummy gate;
etching the first source and the first drain sides of the first logic area to expose the substrate;
etching the second source and the second drain sides of the second logic area to expose the substrate;
forming first inner spacers in the first gate region vertically below the first upper spacers, the first inner spacers alternatively stacked with the nanosheets in the first gate region;
forming the second inner spacers in the second gate region vertically below the second upper spacers, the second inner spacers alternatively stacked with the nanosheets in the second gate region;
growing the first source on the first source side in the first gate region;
growing the second source on the second source side in the second gate region;
stripping the dummy layers and the first dummy gate in the first gate region;
stripping the dummy layers and the second dummy gate in the second gate region;
forming the first gate in the first gate region in place of the first dummy gate and the dummy layers; and
forming the second gate in the second gate region in place of the second dummy gate and the dummy layers.

30. The method of claim 29, wherein providing the nanosheet wafer with N nanosheets and N dummy layers alternatively stacked above the substrate in the first logic area and with N−M nanosheets and N−M+1 dummy layers alternatively stacked above the substrate in the second logic area comprises:
providing the nanosheet wafer with N nanosheets and N dummy layers alternatively stacked above the substrate;
etching the second logic area of the nanosheet wafer, wherein upper most M nanosheets are removed in the second logic area;
forming temporary spacers on sides of etched space of the second logic area; and
growing a dummy layer within the etched space of the second logic area, the dummy layer being coplanar with upper most nanosheet.
